(19) United States
(12) Patent Application Publication
(10) Pub. No.: US 2014/0048131 A1
(43) Pub. Date: Feb. 20, 2014

(54) CONDUCTIVE MEMBER, PRODUCTION METHOD OF THE SAME, TOUCH PANEL, AND SOLAR CELL

(71) Applicant: FUJIFILM Corporation, Tokyo (JP)

(72) Inventors: Satoshi TANAKA, Kanagawa (JP); Shinichi NAKAHIRA, Kanagawa (JP); Yuki MATSUNAMI, Kanagawa (JP); Tomohito ASAI, Kanagawa (JP)

(73) Assignee: FUJIFILM Corporation, Tokyo (JP)

(21) Appl. No.: 14/062,244

(22) Filed: Oct. 24, 2013

Related U.S. Application Data
(63) Continuation of application No. PCT/JP2012/061463, filed on Apr. 27, 2012.

(30) Foreign Application Priority Data
Apr. 28, 2011 (JP) 2011-102135
Dec. 2, 2011 (JP) 2011-265207
Mar. 23, 2012 (JP) 2012-068270

(51) Int. Cl. H05K 1/09; H01L 31/18; H01L 31/0224

(52) U.S. Cl. CPC H05K 1/092; H01L 31/022425; H01L 31/186
USPC 136/256; 174/250; 174/257; 427/74; 427/123

(57) ABSTRACT

A conductive member containing a base material and a conductive layer provided on the base material, wherein the conductive layer includes (i) a metallic nanowire having an average short-axis length of 150 nm or less and (ii) a binder, the binder including a three-dimensional crosslinked structure that includes a partial structure represented by the following Formula (Ia) and a partial structure represented by the following Formula (IIa) or Formula (IIb). In the Formulae, each of M¹ and M² independently represents an element selected from the group consisting of Si, Ti and Zr. Each R3 independently represents a hydrogen or a hydrocarbon group.

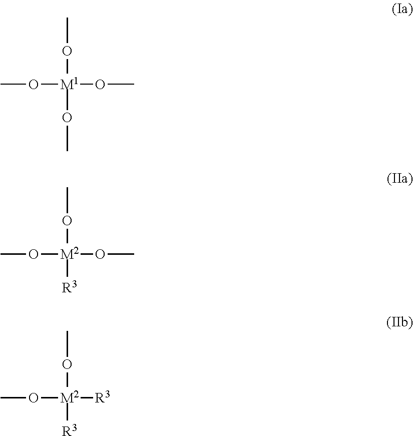

### CROSS-REFERENCE TO RELATED APPLICATION

This application is a continuation application of, and claims priority to, International Application No. PCT/JP2012/061463, filed Apr. 27, 2012, which is incorporated herein by reference. Further, this application claims priority from Japanese Patent Application Nos. 2011-102135, filed Apr. 28, 2011, 2011-265207, filed Dec. 2, 2011, and 2012-068270, filed Mar. 23, 2012, which are incorporated herein by reference.

### BACKGROUND OF THE INVENTION

1. Technical Field

The present invention relates to a conductive member, a production method of the conductive member, a touch panel and a solar cell.

2. Background Art

Recently, a conductive member having a conductive layer including conductive fibers such as metallic nanowires has been proposed (for example, refer to Japanese National Phase Publication (JP-A) No. 2009-505358). This conductive member has a conductive layer including plural metallic nanowires on a substrate. The conductive member can be easily processed into a conductive member having a conductive layer including a desired conductive area and a desired non-conductive area by, for example, containing a photocurable composition as a matrix in the conductive layer and carrying out pattern exposure and subsequent development. The conductive member processed as above can be used in, for example, touch panels or electrodes in solar cells.

It is also described that the conductive layer in the conductive member has a conductive member dispersed or buried in a matrix material in order to improve the physical and mechanical properties. As the matrix material, an inorganic material such as a sol-gel matrix is exemplified (for example, refer to paragraphs [0045] to [0046] and [0051] of Japanese National Phase Publication (JP-A) No. 2009-505358).

A conductive member provided with a conductive layer containing a transparent resin and a fiber-shaped conductive substance such as a metallic nanowire on a base material as a conductive layer having both high transparency and high conduction has been proposed. As the transparent resin, a resin obtained by thermally polymerizing a compound such as alkoxysilane or alkoxytitanium using a sol-gel method has been exemplified (for example, refer to Japanese Patent Application Laid-Open (JP-A) No. 2010-121040).

### SUMMARY OF INVENTION

### Technical Problem

When a touch panel operation such as the rubbing of the surface of the conductive layer with a tool having a pointed tip such as a pencil or a touch panel stylus is repeated, the surface of the conductive layer is damaged or worn, and therefore, in the conductive member, there is still room for improving the film strength and abrasion resistance of the conductive layer.

In a case in which the conductive member is used in a flexible touch panel, there are cases in which cracking and the like occur in the conductive layer due to the repetition of a folding operation over a long period of time and thus the conduction degrades, and therefore, there is still room for improving the bending resistance.

When it comes to conductive members with a conductive layer including metallic nanowires, there has been a demand for conductive members which have high conduction, high transparency and high film strength, and are excellent in terms of abrasion resistance and bending resistance.

The invention can provide a conductive member which has high conduction, high transparency and high film strength, and is excellent in terms of abrasion resistance and bending resistance, a production method of the same, and a touch panel and a solar cell in which the conductive member is used.

### Solution to Problem

Exemplary embodiments of the present invention include the following.

<1> A conductive member including: a base material; and a conductive layer provided on the base material, the conductive layer including (i) a metallic nanowire having a n average short-axis length of 150 nm or less, and (ii) a binder, and the binder including a three-dimensional crosslinked structure that contains a partial structure represent ed by the following Formula (Ia) and a partial structure represented by the following Formula (IIa) or the following Formula (IIb).

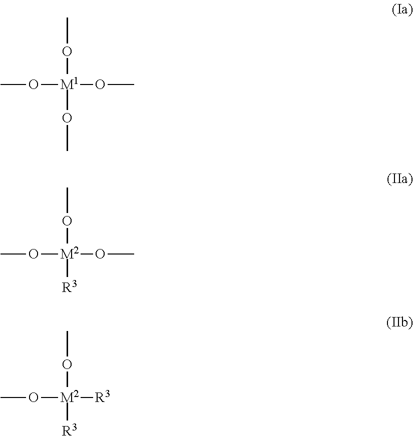

In the Formulae, each of M¹ and M² independently represents an element selected from the group consisting of Si, Ti, and Zr; and each R³ independently represent a hydrogen atom or a hydrocarbon group.

<2> A conductive member including: a base material; and a conductive layer provided on the base material, the conductive layer including (i) a metallic nanowire having an average short-axis length of 150 nm or less, and (ii) a sol-gel cured product, the sol-gel cured product being formed through hydrolysis and condensation of a tetraalkoxy compound represented by the following Formula (I) and an organoalkoxy compound represented by the following Formula (II):

M¹(OR¹)₄ Formula (I)

wherein, in Formula (I), M¹ represents an element selected from the group consisting of Si, Ti, and Zr; and R¹ represents a hydrocarbon group,

M²(OR²)ₐR³₄₋ₐ Formula (II)

wherein, in Formula (II), M² represents an element selected from the group consisting of Si, Ti, and Zr; each R² and each R³ independently represents a hydrogen atom or a hydrocarbon group; and “a” represents an integer of 2 or 3.

<3> The conductive member according to the item <2>, wherein a mass ratio of a content of the tetraalkoxy compound to a content of the organoalkoxy compound in the conductive layer is in a range of from 0.01/1 to 100/1.

<4> The conductive member according to the item <2>, wherein a mass ratio of a total content of the tetraalkoxy compound and the organoalkoxy compound to a content of the metallic nanowire in the conductive layer is in a range of from 0.5/1 to 25/1.

<5> The conductive member according to the item <1> or the item <2>, wherein both of M¹ and M² are Si.

<6> The conductive member according to the item <1> or the item <2>, wherein the metallic nanowire is a silver nanowire.

<7> The conductive member according to the item <1> or the item <2>, wherein a surface resistivity measured at a surface of the conductive layer is 1,000Ω/□ or less.

<8> The conductive member according to the item <1> or the item <2>, wherein an average film thickness of the conductive layer is in a range of from 0.005 μm to 0.5 μm.

<9> The conductive member according to the item <1> or the item <2>, wherein the conductive layer includes a conductive region and a nonconductive region, and at least the conductive region includes the metallic nanowire.

<10> The conductive member according to the item <1> or the item <2>, wherein the conductive member further includes at least one intermediate layer between the base material and the conductive layer.

<11> The conductive member according to the item <1> or the item <2>, wherein the conductive member further includes an intermediate layer between the base material and the conductive layer, the intermediate layer contacts the conductive layer, and the intermediate layer includes a compound having a functional group that interacts with the metallic nanowire.

<12> The conductive member according to the item <11>, wherein the functional group is selected from the group consisting of an amido group, an amino group, a mercapto group, a carboxylic acid group, a sulfonic acid group, a phosphoric acid group, a phosphonic acid group and a salt thereof.

<13> The conductive member according to the item <1> or the item <2>, w herein a ratio of a surface resistivity (Ω/□) of the conductive layer after an abrasion treatment to a surface resistivity (Ω/□) of the conductive layer before the abrasion treatment is 100 or less, the abrasion treatment being performed by reciprocating a gauze 50 times on the surface of the conductive layer under a load of 125 g/cm² using a continuous loading scratching intensity tester.

<14> The conductive member according to the item <1> or the item <2>, w herein a ratio of a surface resistivity (Ω/□) of the conductive layer after a bending tes t to a surface resistivity (Ω/□) of the conductive layer before the bending test is 2.0 or less, the bending test being performed by bending the conductive member 20 times using a cylindrical mandrel bending tester provided with a cylindrical mandrel having a diameter of 10 mm.

<15> A production method of the conductive member according to any one of the items <2> to <4> including: (a) applying a liquid composition including the metallic nanowire, the tetraalkoxy compound and the organoalkoxy compound onto the base material to form a liquid film of the liquid composition on the base material; and

(b) hydrolyzing and condensing the tetraalkoxy compound and the organoalkoxy compound in the liquid film to form the sol-gel cured product.

<16> The production method of the conductive member according to the item <15>, further including forming at least one intermediate layer on a surface of the b ase material, at which the liquid film is to be formed, prior to the process (a).

<17> The production method of the conductive member according to the item <15> or the item <16>, further including (c) forming a patterned non-conductive region in the conductive layer after the process (b) such that the conductive layer has a conductive region and a non-conductive region.

<18> The production method of the conductive member according to the item <15> or the item <16>, wherein a mass ratio of a content of the tetraalkoxy compound to a content of the organoalkoxy compound in the conductive layer is in a range of from 0.01/1 to 100/1.

<19> The production method of the conductive member according to the item <15> or the item <16>, wherein a mass ratio of a total content of the tetraalkoxy compound and the organoalkoxy compound to a content of the metallic nanowire in the conductive layer is in a range of from 0.5/1 to 25/1.

<20> A composition including: (i) a metallic nanowire having an average short-axis length of 150 nm or less; (ii) a tetraalkoxy compound represented by the following Formula (I) and an organoalkoxy compound represented by the following Formula (II); and (iii) a liquid dispersion medium that disperses or dissolves the component (i) and the component (ii);

M¹(OR¹)₄ Formula (I)

wherein, in Formula (I), M¹ represents an element selected from the group consisting of Si, Ti, and Zr; and R¹ represents a hydrocarbon group,

M²(OR²)ₐR³₄₋ₐ Formula (II)

wherein, in Formula (II), M² represents an element selected from the group consisting of Si, Ti, and Zr; each R² and each R³ independently represent a hydrogen atom or a hydrocarbon group; and “a” represents 2 or 3.

<21> A touch panel including the conductive member according to any one of the items <1> to <14>.

<22> A solar cell including the conductive member according to any one of the items <1> to <14>.

### Advantageous Effects of Invention

According to the invention, it is possible to provide a conductive member which has high conduction, high transparency and high film strength, and is excellent in terms of abrasion resistance and bending resistance, a production method of the same, a touch panel and a solar cell for both of which the conductive member is used.

### BRIEF DESCRIPTION OF DRAWINGS

FIG. 1 is a schematic cross-sectional view illustrating a first exemplary aspect of the conductive member according to the first embodiment of the invention.

FIG. 2 is a schematic cross-sectional view illustrating a second exemplary aspect of the conductive member according to the first embodiment of the invention.

### DESCRIPTION OF EMBODIMENTS

Hereinafter, the invention will be described based on a representative embodiment of the invention, but the invention is not limited to the described embodiment unless exceeding the purport of the invention.

In the present disclosure, the scope of “step” includes not only independent steps but also steps that cannot be clearly differentiated from other steps as long as the steps can achieve desired actions.

The expression of numeric ranges (“m or more and n or less” or “m to n”) indicates a range including the numerical value (m) expressed as the lower limit value of the numerical range as the minimum value and the numerical value (n) expressed as the upper limit value of the numerical range as the maximum value.

In a case in which the amount of a component in a composition is mentioned, when plural substances that belong to the component are present in the composition, the amount indicates the total amount of the plural substances present in the composition unless particularly otherwise defined.

Conceptually, the word “light” used in the specification includes not only visible light rays but also high-energy rays such as ultraviolet rays, X-rays and gamma rays, particle rays such as electron beams, and the like.

In the specification, “(meth)acrylic acid” represents either or both of acrylic acid and methacrylic acid, and “(meth)acrylate” represents either or both of acrylate and methacrylate.

In addition, the content will be expressed by mass unless particularly otherwise described, % by mass represents the proportion of a composition in a total amount unless particularly otherwise described, and “solid content” refers to components of a composition except for volatile components such as a solvent.

<<Conductive Member>>

The conductive member that is an embodiment of the invention has a base material and a conductive layer provided on the base material. The conductive layer includes (i) metallic nanowires having an average short-axis length of 150 nm or less and (ii) a binder. The binder has a three-dimensional crosslinked structure including a substructure represented by Formula (Ia) and a substructure represented by Formula (IIa) or (IIb). The conductive member may further include other components as necessary.

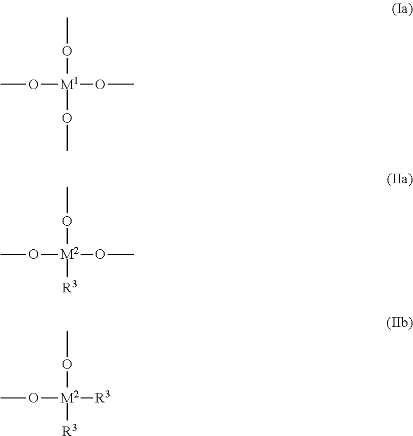

In Formula (Ia), Formula (IIa) and Formula (IIb), each of M1 and M2 independently represents an element selected from a group consisting of Si, Ti and Zr. Each of R3 independently represents a hydrogen atom or a hydrocarbon group.

When the conductive layer includes a binder having a specific substructure in addition to the metallic nanowires having an average short-axis length of 150 nm or less, the conductive member can have high conduction, high transparency and high film strength, and be excellent in terms of abrasion resistance and bending resistance.

In addition, the binder has a three-dimensional crosslinked structure including at least one substructure selected from a group consisting of the substructure (organometallic structures) represented by Formula (IL) and the substructure represented by Formula (IIa) in addition to the substructure represented by Formula (Ia). When the binder further includes the organometallic structure in addition to the substructure represented by Formula (Ia) as described above, the binder may have improved flexibility and excellent bendability, and develop excellent film strength and excellent abrasion resistance in a well-balanced manner.

The binder may be any of a binder having the substructure represented by Formula (Ia) and the substructure represented by Formula (IL), a binder having the substructure represented by Formula (Ia) and the substructure represented by Formula (IIb) and a binder having the substructure represented by Formula (Ia), the substructure represented by Formula (IIa) and the substructure represented by Formula (IIb).

In an embodiment, when M¹ and M² are Si, the conductive member can be superior in terms of film strength, abrasion resistance and bending resistance.

R³ indicates a hydrogen atom or a hydrocarbon group, and is preferably a hydrocarbon group from the viewpoints of film strength, abrasion resistance and bending resistance. The hydrocarbon group of R³ preferably includes an alkyl group or an aryl group.

In a case in which R³ indicates an alkyl group, the number of carbon atoms thereof is preferably from 1 to 18, more preferably from 1 to 8, and still more preferably from 1 to 4. In addition, in a case in which R³ indicates an aryl group, the aryl group is preferably a phenyl group.

The alkyl group or the aryl group in R³ may have a substituent. Examples of the substituent that can be introduced include a halogen atom, an acyloxy group, an alkenyl group, an acryloyloxy group, methacryloyloxy group, an amino group, an alkylamino group, a mercapto group, an epoxy group and the like.

In the conductive layer containing the binder, the molar ratio (M¹/M²) of the content of an element M¹ included in the substructure represented by Formula (Ia) to the total content of an element M² included in the substructure represented by Formula (IIa) and the substructure represented by Formula (IIb) is preferably from 0.01/1 to 100/1, more preferably from 0.02/1 to 50/1, and still more preferably from 0.05/1 to 20/1 from the viewpoints of film strength, abrasion resistance and bending resistance.

The binder having the substructure represented by Formula (Ia) and at least one substructure selected from a group consisting of the substructure represented by Formula (IIa) and the substructure represented by Formula (IIb) can be confirmed by measuring the solid NMR (nuclear magnetic resonance) of the conductive layer and detecting signals that correspond to the respective substructures.

The molar ratio (M¹/M²) of the content of the element M¹ to the content of the element M² in the conductive layer can be obtained by, for example, detaching the conductive layer from the base material, measuring the solid NMR of the conductive layer, and obtaining the ratio of the integrated value of signals that correspond to M¹ to the integrated value of signals that correspond to M². Specifically, in a case in which M¹ and M² are Si, the solid-state ²⁹Si-NMR (CP/Mas method, observation frequency ²⁹Si: 59.62 MHz) is measured using an AVANCE DSX-300 spectrometer (trade name) manufactured by Bruker Corporation. A signal with a chemical shift in a range of from −70 ppm to −120 ppm is a peak of Si corresponding to Formula (Ia), a signal with a chemical shift in a range of from 5 ppm to −35 ppm is a peak of Si corresponding to Formula (IIb), and a signal with a chemical shift in a range of from −35 ppm to −70 ppm is a peak of Si corresponding to Formula (IIa). From the integrated value of the signals, the molar ratio of M¹ to M² can be computed.

The binder can be obtained in a form of a cured sol-gel substance by hydrolyzing and polycondensing a mixture of a tetraalkoxy compound that can form the substructure represented by Formula (Ia) and an organoalkoxy compound that can form the substructure represented by Formula (IIa) and the substructure represented by Formula (IIb). The detail of the cured sol-gel substance will be described below.

The metallic nanowires included in the conductive layer has an average short-axis length of 150 nm or less. Thereby, the conductive layer can be excellent in terms of conduction and transparency. The detail of the metallic nanowires will be described below.

The conductive layer includes the metallic nanowires and the binder. The molar ratio ((M¹+M²)/metal elements) of the total content of the elements M¹ and M² that configure the binder to the content of metal elements that configure the metallic nanowires in the conductive layer is preferably from 0.10/1 to 22/1, more preferably from 0.20/1 to 18/1, and still more preferably from 0.45/1 to 15/1 from the viewpoints of film strength, abrasion resistance and bending resistance.

The molar ratio ((M¹+M²)/metal elements) can be computed by subjecting the conductive layer to an X-ray photoelectric analysis (electron spectroscopy for chemical analysis (ESCA)). In the analysis method using ESCA, since the measurement sensitivity varies depending on elements, obtained values do not directly correspond to the molar ratio of element components at all times. Therefore, a calibration curve is produced using a conductive layer with an already-known molar ratio of element components, and the molar ratio ((M¹+M²)/metal elements) is computed.

The conductive layer in the conductive member preferably contains (i) the metallic nanowires having an average short-axis length of 150 nm or less and (ii) the cured sol-gel substance obtained by hydrolyzing and polycondensing a tetraalkoxy compound represented by Formula (I) and an organoalkoxy compound represented by Formula (II).

That is, in a preferable aspect, the conductive member includes a base material and a conductive layer provided on the base material containing (i) metallic nanowires having an average short-axis length of 150 nm or less and (ii) a binder that is a cured sol-gel substance obtained by hydrolyzing and polycondensing a tetraalkoxy compound represented by Formula (I) and an organoalkoxy compound represented by Formula (II).

M¹(OR¹)₄ Formula (I)

(In Formula (I), M¹ represents an element selected from a group consisting of Si, Ti and Zr, and R¹ represents a hydrocarbon group.)

M²(OR²)ₐR³₄₋ₐ Formula (II)

(In Formula (II), M² represents an element selected from a group consisting of Si, Ti and Zr, each of R² and R³ independently represents a hydrogen atom or a hydrocarbon group, and a represents an integer of 2 or 3.)

<<Base Material>>

As the base material, a variety of base materials can be used depending on the purpose as long as the base material can bear the conductive layer. Generally, a plate-like base material or a sheet-like base material is used.

The base material may be transparent or opaque. Examples of a material that forms the base material include transparent glass such as white plate glass, blue plate glass and silica-coated blue plate glass; synthesis resins such as polycarbonates, polyethersulfones, polyesters, acrylic resins, vinyl chloride resins, aromatic polyamide resins, polyamide-imides and polyimides; metal such as aluminum, copper, nickel and stainless steel; additionally, ceramics, silicon wafers used for semiconductor substrates, and the like. A surface of the base material on which the conductive layer is formed can be subjected to a pretreatment such as a chemical treatment using a silane coupling agent or the like, a plasma treatment, ion plating, sputtering, a gas-phase reaction or vacuum deposition as desired.

A base material with a thickness in a desired range depending on the use may be used. The thickness is generally selected from a range of from 1 μm to 500 μm, more preferably from 3 μm to 400 μm, and still more preferably from 5 μm to 300 μm.

In a case in which a transparent conductive member is required, a conductive member including a base material having a total visible light transmittance of 70% or more, more preferably 85% or more, and still more preferably 90% or more is selected. Meanwhile, the total light transmittance of the base material is measured based on ISO 13468-1 (1996).

<<Conductive Layer>>

The conductive layer contains (i) the metallic nanowires having an average short-axis length of 150 nm or less and (ii) the binder that is the cured sol-gel substance obtained by hydrolyzing and polycondensing a tetraalkoxy compound represented by Formula (I) and an organoalkoxy compound represented by Formula (II).

<Metallic Nanowires Having an Average Short-Axis Length of 150 nm or Less>

The conductive layer contains the metallic nanowires having an average short-axis length of 150 nm or less. When the average short-axis length exceeds 150 nm, there is a concern that the optical characteristics may be deteriorated due to the degradation of conduction, light scattering or the like, which is not preferable. The metallic nanowire preferably has a solid structure.

From the viewpoint of the easy formation of more transparent conductive layers, the metallic nanowires have, for example, an average short-axis length of from 1 nm to 150 nm and an average long-axis length of from 1 μm to 100 μm.

For the easy handling during production, the average short-axis length (average diameter) of the metallic nanowires is preferably 100 nm or less, more preferably 60 nm or less, and still more preferably 50 nm or less, and an average short-axis length of 30 nm or less is particularly preferable since conductive layers with superior haze-related properties can be obtained. When the average short-axis length is set to 1 nm or more, conductive members with favorable oxidation resistance and excellent climate resistance are easily obtained. The average short-axis length is more preferably 5 nm or more, still more preferably 10 nm or more, and particularly preferably 20 nm or more.

From the viewpoint of inhibition of haze, oxidation resistance and climate resistance, the average short-axis length of the metallic nanowires is preferably from 1 nm to 100 nm, more preferably from 5 nm to 60 nm, still more preferably from 10 nm to 60 nm, and particularly preferably from 20 nm to 50 nm.

The average long axis length of the metallic nanowires is preferably 1 μm to 40 μm, more preferably 3 μm to 35 μm, and still more preferably 5 μm to 30 μm. When the average long axis length of the metallic nanowires is 40 μm or less, it becomes easy to synthesize the metallic nanowires without agglomerates being generated. In addition, when the average long axis length is 1 μm or more, it becomes easy to obtain a sufficient conduction.

Here, the average short axis length (average diameter) and average long axis length of the metallic nanowires can be obtained by, for example, observing TEM images or optical microscopic images using a transmission electron microscope (TEM) or an optical microscope. Specifically, the average short axis length (average diameter) and average long axis length of the metallic nanowires can be obtained by measuring the short axis lengths and long axis lengths of 300 randomly-selected metallic nanowires using a transmission electron microscope (TEM; JEM-2000FX; trade name, manufactured by JELO Ltd.) and computing the average values. Meanwhile, in a case in which the cross-section of the metallic nanowire in the short axis direction was not round, the length of the longest place in a measurement in the short axis direction was used as the short axis length. In addition, in a case in which the metallic nanowire was curved, a circle having the curve as an arc was considered, and the length of a circular arc computed from the radius and curvature of the circle was used as the long axis length.

In an embodiment, the content of the metallic nanowires having a short-axis length (diameter) of 150 nm or less and a long-axis length of from 5 μm to 500 μm with respect to the content of all the metallic nanowires in the conductive layer is preferably 50% by mass or more, more preferably 60% by mass or more, and still more preferably 75% by mass or more in terms of the amount of metal.

When the proportion of the metallic nanowires having a short-axis length (diameter) of 150 nm or less and a long-axis length of from 5 μm to 500 μm is 50% by mass, sufficient conduction can be obtained, voltage concentration does not easily occur, and the voltage concentration-induced degradation of durability can be suppressed, which is preferable. In a configuration in which the conductive layer does not substantially include non-fibrous conductive particles, the degradation of transparency can be avoided even in a case in which plasmon absorption is strong.

A coefficient of variation of the short axis length (diameter) of the metallic nanowires used in the conductive layer in the invention is preferably 40% or less, more preferably 35% or less, and still more preferably 30% or less.

When the coefficient of variation exceeds 40%, there are cases in which durability deteriorates probably because voltage concentrates in wires with a small short axis length (diameter).

The coefficient of variation of the short axis length (diameter) of the metallic nanowires can be obtained by, for example, measuring the short axis lengths (diameters) of 300 nanowires on a transmission electron microscopic (TEM) image, and computing the standard deviation and average value.

(Aspect Ratio of the Metallic Nanowires)

An aspect ratio of the metallic nanowires is preferably 10 or more. Here, the aspect ratio refers to a ratio of the average long axis length to the average short axis length. The aspect ratio can be computed using the average long axis length and the average short axis length computed using the above method.

The aspect ratio of the metallic nanowires is not particularly limited as long as the aspect ratio is 10 or more, and can be appropriately selected depending on the purpose, but is preferably from 10 to 100,000, more preferably from 50 to 100,000, and even more preferably from 100 to 100,000.

When the aspect ratio is set to 10 or more, a network in which the metal nanowires are in contact with each other is easily formed, and a conductive layer having a high conduction can be easily obtained. In addition, when the aspect ratio is set to 100,000 or less, for example, it is possible to obtain a coating liquid used when providing the conductive layer on the base material through coating which is quite stable that there is no concern that the metallic nanowires may tangle and agglomerate, and therefore it becomes easy to produce the conductive layer.

A content rate of the metallic nanowires having an aspect ratio of 10 or more included in the metallic nanowires included in the conductive layer is not particularly limited, but is preferably, for example, 70% by mass or more, more preferably 75% by mass or more, and even more preferably 80% by mass or more.

A shape of the metallic nanowire can be any shape such as a cylindrical shape, a cuboid shape or a columnar shape having a polygonal cross-section, but metallic nanowires having a cross-sectional shape that is a columnar shape or an pentagonal or more polygonal shape and has no sharp angle are preferable for use in which a high transparency is required.

The cross-sectional shape of the metallic nanowire can be detected by coating a metallic nanowire aqueous dispersion liquid on the base material, and observing the cross-section using a transmission electron microscope (TEM).

The metal of the metallic nanowires is not particularly limited, may be any metal or a combination of two kinds of metal, and also can be used in a form of an alloy. Among the above, metallic nanowires formed of metal or a metallic compound are preferable, and metallic nanowires formed of metal are more preferable.

The metal is preferably at least one kind of metal selected from a group consisting of Periods 4, 5 and 6 of the long-form periodic table (IUPAC 1991), more preferably at least one kind of metal selected from Groups 2 to 14, and still more preferably at least one kind of metal selected from Groups 2, 8, 9, 10, 11, 12, 13 and 14. The metal is particularly preferably included as a main component.

Specific examples of the metal include copper, silver, gold, platinum, palladium, nickel, tin, cobalt, rhodium, iridium, iron, ruthenium, osmium, manganese, molybdenum, tungsten, niobium, tantalum, titanium, bismuth, antimony, lead, alloys thereof and the like. Among the above, copper, silver, gold, platinum, palladium, nickel, tin, cobalt, rhodium, iridium or an alloy thereof is preferable, and palladium, copper, silver, gold, platinum, tin or an alloy thereof is more preferable, and silver or an alloy containing silver is particularly preferable. A content of the silver in the alloy containing silver is preferably 50% by mole, more preferably 60% by mole, and even more preferably 80% by mole with respect to a total mole of the alloy.

From the viewpoint of a high conduction, the metallic nanowires included in the conductive layer preferably include silver nanowires, more preferably include silver nanowires having an average short axis length of from 1 nm to 150 nm and an average long axis length of from 1 μm to 100 μm, and still more preferably include silver nanowires having an average short axis length of from 5 nm to 30 nm and an average long axis length of from 5 μm to 30 μm. A content rate of the silver nanowires included in the metal nanowires with respect to a total mass of the metallic nanowires included in the conductive layer is not particularly limited as long as the effects of the invention are not hindered. For example, the content rate of the silver nanowires in the metal nanowires is preferably 50% by mass or more, and more preferably 80% by mass or more with respect to the total mass of the metallic nanowires included in the conductive layer, and the metallic nanowires are still more preferably substantially silver nanowires. Here, the “substantially silver nanowires” mean that silver nanowires may include metallic atoms other than silver which are inevitably mixed in.

The content of the metallic nanowires included in the conductive layer is preferably set depending on the kind and the like of the metallic nanowires to an amount at which the surface resistivity, light transmittance and haze value of the conductive member are in desired ranges. The content (the content (grams) of the metallic nanowires per square meter of the conductive layer) is in a range of from 0.001 g/m² to 0.100 g/m², preferably in a range of from 0.002 g/m² to 0.050 g/m², and more preferably in a range of from 0.003 g/m² to 0.040 g/m² in the case of, for example, silver nanowires.

The conductive layer preferably includes the metallic nanowires having an average short-axis length of from 5 nm to 60 nm in a range of from 0.001 g/m² to 0.100 g/m², more preferably includes the metallic nanowires having an average short-axis length of from 10 nm to 60 nm in a range of from 0.002 g/m² to 0.050 g/m², and still more preferably includes the metallic nanowires having an average short-axis length of from 20 nm to 50 nm in a range of from 0.003 g/m² to 0.040 g/m² from the viewpoint of conduction.

(Production Method of the Metallic Nanowires)

The metallic nanowires are not particularly limited, and may be manufactured using any method, but are preferably produced by reducing metallic ions in a solvent in which a halogen compound and a dispersant are dissolved as described below. In addition, from the viewpoint of dispersibility and the stability of a photosensitive layer over time, it is preferable to form metallic nanowires and then carry out a desalination treatment using a normal method.

In addition, methods described in JP-A No. 2009-215594, JP-A No. 2009-242880, JP-A No. 2009-299162, JP-A No. 2010-84173, JP-A No. 2010-86714 and the like can be used as the production method of the metallic nanowires.

The solvent used for the production of the metallic nanowires is preferably a hydrophilic solvent, and examples thereof include water, alcohols, ethers, ketones and the like. One of the above solvents may be solely used, or two or more may be used in a combination.

Examples of the alcohols include methanol, ethanol, propanol, isopropanol, butanol, ethylene glycol and the like.

Examples of the ethers include dioxane, tetrahydrofuran and the like.

Examples of the ketones include acetone and the like.

In a case in which metallic nanowires are heated in a process of the production of the metallic nanowires, the heating temperature is preferably 250° C. or lower, more preferably from 20° C. to 200° C., still more preferably from 30° C. to 180° C., and particularly preferably from 40° C. to 170° C. When the temperature is set to 20° C. or higher, the lengths of metallic nanowires being formed are in a range in which dispersion stability can be ensured, and, when the temperature is set to 250° C. or lower, the outer circumferences of the cross-sections of metallic nanowires have a smooth shape with no sharp angle, and thus the temperature of 250° C. or lower is preferably from the viewpoint of transparency.

Meanwhile, the temperature may be changed as necessary in a particle-forming process, and there are cases in which the change of the temperature in the middle of the process has effects of controlling the formation of nuclei, suppressing the regeneration of nuclei, and improving monodispersibility through acceleration of selective growth.

When metallic nanowires are heated, a reducing agent is preferably added.

The reducing agent is not particularly limited, can be appropriately selected from ordinarily-used reducing agents, and examples thereof include borane metallic salts, aluminum hydride salts, alkanolamines, aliphatic amines, heterocyclic amines, aromatic amines, aralkylamines, alcohols, organic acids, reducing sugars such as glucose, sugar alcohols, sodium sulfite, hydrazine compounds, dextrins, hydroquinones, hydroxylamines, ethylene glycols, glutathiones, and the like. Among the above, reducing sugars, sugar alcohols as derivatives of the reducing sugars, and ethylene glycols are particularly preferable.

Among the reducing agents, there are compounds that function as a dispersant or a solvent, and the compounds can be preferably used in a substantially similar manner.

The metallic nanowires are preferably produced by adding a dispersant, a halogen compound or fine particles of a metal halide.

The dispersant and the halogen compound may be added before or after the addition of the reducing agent, or before or after the addition of metallic ions or fine particles of a metal halide; however, in order to obtain nanowires having a more favorable monodispersibility, the halogen compound is preferably added at two or more steps probably because it is considered that the formation and growth of nuclei can be controlled by the steps.

A process of the addition of the dispersant is not particularly limited. The dispersant may be added before the preparation of the metallic nanowires, and the metallic nanowires may be formed in the presence of the added dispersants. Alternatively, the dispersant may be added after the preparation of the metallic nanowires in order to control the dispersed state of the metallic nanowires.

Examples of the dispersant include amino group-containing compounds, thiol group-containing compounds, sulfide group-containing compounds, amino acids or derivatives thereof, macromolecules such as peptide compounds, polysaccharides, polysaccharide-derived natural macromolecules, synthetic macromolecules and gel derivatives, and the like. Among the above, a variety of macromolecular compounds that can be used as the dispersant are compounds included in polymers described below.

Preferable examples of polymers preferably used as the dispersant include polymers having a hydrophilic group such as gelatin, polyvinyl alcohols, methyl celluloses, hydroxypropyl celluloses, polyalkyleneamines, partial alkylesters of polyacrylic acids, polyvinyl pyrrolidones, copolymers having a polyvinyl pyrrolidone structure, and polyacrylic acid derivatives having an amino group or a thiol group, which is a protective colloidal polymer.

A polymer used as the dispersant has a GPC-measured weight-average molecular weight (Mw) of preferably from 3000 to 300000 and more preferably from 5000 to 100000.

Regarding the structures of the compounds that can be used as the dispersant, for example, “DICTIONARY OF DYES” (by Hiroyuki Ito, published by ASAKURA PUBLISHING Co., Ltd., 2000) can be referenced.

The shapes of metallic nanowires being obtained can be changed depending on the kind of the dispersant being used.

The halogen compound is not particularly limited as long as the compound includes bromine, chlorine and iodine, can be appropriately selected depending on the purpose, and preferable examples thereof include alkali halides such as sodium bromide, sodium chloride, sodium iodide, potassium iodide, potassium bromide and potassium chloride, or compounds that can be jointly used with a dispersion additive described below.

Some of the halogen compounds might be capable of functioning as a dispersion additive, and they can be preferably used in a substantially similar manner.

As an alternative of the halogen compound, fine particles of silver halide may be used, or the halogen compound and fine particles of silver halide may be jointly used.

In addition, as the dispersant and the halogen compound, a sole substance having both functions may be used. That is, when a halogen compound having a function of a dispersant is used, both functions as the dispersant and the halogen compound are developed using a compound.

Examples of the halogen compound having a function of a dispersant include hexadecyltrimethylammonium bromide (HTAB) including an amino group and bromide ions, hexadecyltrimethylammonium chloride (HTAC) including an amino group and chloride ions, compounds including an amino group and bromide ions or chloride ions such as dodecyltrimethylammonium bromide, dodecyltrimethylammonium chloride, stearyltrimethylammonium bromide, stearyltrimethylammonium chloride, decyltrimethylammonium bromide, decyltrimethylammonium chloride, dimethyldistearylammonium bromide, dimethyldistearylammonium chloride, dilauryldimethylammonium bromide, dilauryldimethylammonium chloride, dimethyldipalmitylammonium bromide, dimethyldipalmitylammonium chloride and the like.

In a process of a production method of the metallic nanowires, it is preferable that desalination treatment is conducted after the formation of the metallic nanowires. The desalination treatment after the formation of the metallic nanowires can be carried out using a method such as ultrafiltration, dialysis, gel filtration, decantation or centrifugal separation.

The metallic nanowires preferably include inorganic ions, such as alkali metal ions, alkali earth metal ions or halide ions, as little as possible. The electric conductivity of the dispersion of the metallic nanowires dispersed in water is preferably 1 mS/cm or less, more preferably 0.1 mS/cm or less, and still more preferably 0.05 mS/cm or less.

The viscosity of the aqueous dispersion of the metallic nanowires at 20° C. is preferably from 0.5 mPa·s to 100 mPa·s, and more preferably from 1 mPa·s to 50 mPa·s.

The electric conductivity and the viscosity are measured in the aqueous dispersion liquid in which the concentration of the metallic nanowires is 0.40% by mass. When the concentration of the metallic nanowires in the aqueous dispersion liquid is higher than the concentration described above, the measurement of the electric conductivity and the viscosity is performed after dilution of the concentration of the aqueous dispersion liquid with distilled water.

In addition to the metallic nanowires, other conductive materials such as fine conductive particles can be jointly used in the conductive layer as long as the effects of the invention are not impaired, and, from the viewpoint of the effects, a proportion of the metallic nanowires (preferably having an aspect ratio of 10 or more) is preferably 50% by volume or more, more preferably 60% by volume or more, and particularly preferably 75% by volume or more with respect to a total amount of conductive materials including the metallic nanowire. Hereinafter, the proportion of the metallic nanowires will be sometimes called “ratio of the metallic nanowires”.

When the ratio of the metallic nanowires is set to 50% by volume or more, a dense network is formed among the metallic nanowires, and a conductive layer having a high conduction can be easily obtained. Conductive particles having a shape other than metallic nanowires do not significantly contribute to conduction of the conductive layer, in addition that the particles exhibit light absorption in a wave range of visible light, which is not preferable. Particularly, in a case in which the conductive particle is metal and made in a spherical shape such that plasmon absorption is strong, there are cases in which transparency of the conductive layer deteriorates.

Here, the ratio of the metallic nanowires can be obtained by, for example, in a case in which the metallic nanowires are silver nanowires, filtering a silver nanowire aqueous dispersion liquid so as to separate silver nanowires and other particles, and measuring the amount of silver remaining on filtration paper and the amount of silver that has penetrated the filtration paper respectively using an inductively coupled plasma (ICP) atomic emission spectrometer. The ratio of the metallic nanowires is detected by observing the metallic nanowires remaining on the filtration paper using a TEM, observing the short axis lengths of 300 metallic nanowires, and investigating the distribution thereof.

The method for measuring the average short axis length and average long axis length of the metallic nanowires is as described above.

<Cured Sol-Gel Substance>

Next, the cured sol-gel substance of the component (ii) included in the conductive layer will be described.

The cured sol-gel substance is obtained by hydrolyzing and polycondensing a tetraalkoxy compound represented by Formula (I) and an organoalkoxy compound represented by Formula (II).

M¹(OR¹)₄ Formula (I)

(In Formula (I), M¹ represents an element selected from a group consisting of Si, Ti and Zr; and R¹ represents a hydrocarbon group.)

M²(OR²)ₐR³₄₋ₐ Formula (II)

(In Formula (II), M² represents an element selected from a group consisting of Si, Ti and Zr; each R² and each R³ independently represents a hydrogen atom or a hydrocarbon group; and “a” represents an integer of 2 or 3.)

The hydrocarbon group of R¹ in Formula (I) is preferably an alkyl group or an aryl group.

In a case in which R¹ represents an alkyl group, the number of carbon atoms is preferably from 1 to 18, more preferably from 1 to 8, and still more preferably from 1 to 4. In addition, in a case in which R¹ represents an aryl group, the aryl group is preferably a phenyl group.

The alkyl group or the aryl group may or may not include a substituent. Examples of the substituent that can be introduced include a halogen atom, an amino group, a mercapto group and the like. The compound represented by Formula (I) is a low-molecular compound, and the molecular weight is preferably 1000 or less.

The hydrocarbon group of each of R² and R³ in Formula (II) is preferably an alkyl group or an aryl group.

In a case in which each R² and each R³ represents an alkyl group, the number of carbon atoms is preferably from 1 to 18, more preferably from 1 to 8, and still more preferably from 1 to 4. In addition, in a case in which each of R² and R³ represents an aryl group, the aryl group is preferably a phenyl group.

The alkyl group or the aryl group may or may not include a substituent. Examples of the substituent that can be introduced include a halogen atom, an acyloxy group, an alkenyl group, an acryloyloxy group, a methacryloyloxy group, an amino group, an alkylamino group, a mercapto group, an epoxy group and the like.

Each of R² and R³ in Formula (II) is preferably a hydrocarbon group.

Hereinafter, specific examples of the tetraalkoxy compound represented by the Formula (I) will be described, but the invention is not limited thereto.

In a case in which M¹ is Si, that is, examples of the four functional tetraalkoxysilane include tetramethoxysilane, tetraethoxysilane, tetrapropoxysilane, tetrabutoxysilane, methoxytriethoxysilane, ethoxytrimethoxysilane, methoxytripropoxysilane, ethoxytripropoxysilane, propoxytrimethoxysilane, propoxytriethoxysilane, dimethoxydiethoxysilane, or the like. Among the above, particularly preferable examples include tetramethoxysilane, tetraethoxysilane, and the like.

In a case in which M¹ is Ti, that is, examples of the four functional tetraalkoxy titanate include tetramethoxy titanate, tetraethoxy titanate, tetrapropoxy titanate, tetraisopropoxy titanate, tetrabutoxy titanate, or the like.

In a case in which M¹ is Zr, that is, examples of the four functional tetraalkoxy zirconium include a zirconate that corresponds to the compound exemplified as the tetraalkoxy titanate.

Next, specific examples of the organo alkoxy compound represented by the Formula (II) will be described, but the invention is not limited thereto.

In a case in which M³ is Si and a is 2, that is, a difunctional alkoxysilane is, for example, dimethyl dimethoxysilane, diethyl dimethoxysilane, propyl methyl dimethoxysilane, dimethyl diethoxysilane, diethyl diethoxysilane, dipropyl diethoxysilane, γ-chloropropyl methyl diethoxysilane, γ-chloropropyl methyl dimethoxysilane, (p-chloromethyl)phenyl methyl dimethoxysilane, γ-bromopropyl methyl dimethoxysilane, acetoxymethyl methyl diethoxysilane, acetoxymethyl methyl dimethoxysilane, acetoxy propyl methyl dimethoxysilane, benzoyloxypropyl methyl dimethoxysilane, 2-(carbomethoxy)ethyl methyl dimethoxysilane, phenyl methyl dimethoxysilane, phenyl ethyl diethoxysilane, phenyl methyl di-propoxysilane, hydroxymethyl methyl diethoxysilane, N-(methyl-diethoxysilyl-propyl)-O-polyethylene oxide urethane, N-(3-methyl-diethoxysilylpropyl)-4-hydroxy-butylamide, N-(3-methyl-diethoxysilylpropyl) gluconamide, vinyl methyl dimethoxysilane, vinyl methyl diethoxysilane, vinyl methyl dibutoxysilane, isopropenyl methyl dimethoxysilane, isopropenyl methyl diethoxysilane, isopropenyl methyl dibutoxysilane, vinyl methyl bis(2-methoxyethoxy)silane, allyl methyl dimethoxysilane, vinyldecyl methyl dimethoxysilane, vinyloctyl methyl dimethoxysilane, vinylphenyl methyl dimethoxysilane, isopropenylphenyl methyl dimethoxysilane, 2-(meth)acryloyloxyethyl methyl dimethoxysilane, 2-(meth)acryloyloxyethyl methyl diethoxysilane, 3-(meth)acryloyloxypropyl methyl dimethoxysilane, 3-(meth)acryloyloxypropyl methyl diethoxysilane, 3-(meth)acryloyloxypropyl methyl bis(2-methoxyethoxy)silane, 3-[2-(allyloxycarbonyl)phenylcarbonyloxy]propyl methyl dimethoxysilane, 3-(vinyl phenylamino)propyl methyl dimethoxysilane, 3-(vinylphenylamino)propyl methyl diethoxysilane, 3-(vinylbenzylamino)propyl methyl diethoxysilane, 3-(vinylbenzylamino)propyl methyl diethoxysilane, 3-[2-(N-vinylphenylmethylamino)ethyl amino]propyl methyl dimethoxysilane, 3-[2-(N-isopropenylphenylmethylamino)ethylamino]propyl methyl dimethoxysilane, 2-(vinyloxy)ethyl methyl dimethoxysilane, 3-(vinyloxy)propyl methyl dimethoxysilane, 4-(vinyloxy)butyl methyl diethoxysilane, 2-(isopropenyloxy)ethyl methyl dimethoxysilane, 3-(allyloxy)propyl methyl dimethoxysilane, 10-(allyloxycarbonyl)decyl methyl dimethoxysilane, 3-(isopropenylmethyloxy)propyl methyl dimethoxysilane, 10-(isopropenylmethyloxycarbonyl)decyl methyl dimethoxysilane, 3-[(meth)acryloyloxypropyl]methyl dimethoxysilane, 3-[(meth)acryloyloxypropyl]methyl diethoxysilane, 3-[(meth)acryloyloxymethyl]methyl dimethoxysilane, 3-[(meth)acryloyloxymethyl]methyl diethoxysilane, γ-glycidoxypropyl methyl dimethoxysilane, N-[3-(meth)acryloyloxy-2-hydroxypropyl]-3-aminopropyl methyl diethoxysilane, O-[(meth)acryloyloxyethyl]-N-(methyldiethoxysilylpropyl)urethane, γ-glycidoxypropyl methyl diethoxysilane, β-(3,4-epoxycyclohexyl)ethyl methyl dimethoxysilane, γ-aminopropyl methyl diethoxysilane, γ-aminopropyl methyl dimethoxysilane, 4-amino-butyl methyl diethoxysilane, 11-amino-undecyl methyl diethoxysilane, m-aminophenyl methyl dimethoxysilane, p-aminophenyl methyl dimethoxysilane, 3-aminopropyl methyl-bis(methoxyethoxy)silane, 2-(4-pyridylethyl)methyl diethoxysilane, 2-(methyldimethoxysilylethyl)pyridine, N-(3-methyldimethoxysilylpropyl)pyrrole, 3-(m-aminophenoxy)propyl methyl dimethoxysilane, N-(2-aminoethyl)-3-aminopropyl methyl dimethoxysilane, N-(2-aminoethyl)-3-aminopropyl methyl diethoxysilane, N-(6-aminohexyl)amino-methyl methyl diethoxysilane, N-(6-aminohexyl)aminopropyl methyl dimethoxysilane, N-(2-aminoethyl)-11-amino-undecyl methyl dimethoxysilane, (aminoethyl aminomethyl)phenethyl methyl dimethoxysilane, N-3-[(amino(polypropyleneoxy))]aminopropyl methyl dimethoxysilane, n-butylaminopropyl methyl dimethoxysilane, N-ethylaminoisobutyl methyl dimethoxysilane, N-methyl-aminopropyl methyl dimethoxysilane, N-phenyl-γ-amino-propyl methyl dimethoxysilane, N-phenyl-γ-aminomethyl methyl diethoxysilane, (cyclohexylaminomethyl)methyl diethoxysilane, N-cyclohexylaminopropyl methyl dimethoxysilane, bis(2-hydroxyethyl)-3-aminopropyl methyl diethoxysilane, diethylaminomethyl methyl diethoxysilane, diethylaminopropyl methyl dimethoxysilane, dimethylaminopropyl methyl dimethoxysilane, N-3-methyldimethoxysilylpropyl-m-phenylenediamine, N,N-bis[3-(methyldimethoxysilyl)propyl]-ethylenediamine, bis(methyl-diethoxysilylpropyl)amine, bis(methyldimethoxysilylpropyl)amine, bis[(3-methyldimethoxysilyl)propyl]-ethylenediamine, bis[3-(methyldiethoxysilyl)propyl]urea, bis(methyldimethoxysilylpropyl)urea, N-(3-methyl-diethoxysilylpropyl)-4,5-dihydro-imidazole, ureidopropyl methyl diethoxysilane, ureidopropyl methyl dimethoxysilane, acetamidopropyl methyl dimethoxysilane, 2-(2-pyridylethyl)thiopropyl methyl dimethoxysilane, 2-(4-pyridylethyl)thiopropyl methyl dimethoxysilane, bis[3-(methyldiethoxysilyl)propyl]disulfide, 3-(methyldiethoxysilyl)propylsuccinic acid anhydride, γ-mercaptopropyl methyl dimethoxysilane, γ-mercaptopropyl methyl diethoxysilane, isocyanatopropyl methyl dimethoxysilane, isocyanatopropyl methyl diethoxysilane, isocyanatoethyl methyl diethoxysilane, isocyanatomethyl methyl diethoxysilane, carboxyethyl methylsilane diol sodium salt, N-(methyldimethoxysilylpropyl)ethylenediamine triacetic acid trisodium salt, 3-(methyl dihydroxysilyl)-1-propanesulfonic acid, diethyl phosphatoethyl methyl diethoxysilane, 3-methyl-dihydroxysilylpropyl methylphosphonate sodium salt, bis(methyldiethoxysilyl)ethane, bis(methyldimethoxysilyl)ethane, bis(methyldiethoxysilyl)methane, 1,6-bis(methyldiethoxysilyl)hexane, 1,8-bis(methyldiethoxysilyl)octane, p-bis(methyldimethoxysilylethyl)benzene, p-bis(methyldimethoxysilyl)benzene, 3-methoxypropyl methyl dimethoxysilane, 2-[methoxy(polyethyleneoxy)propyl]methyl dimethoxysilane, methoxytriethyleneoxypropyl methyl dimethoxysilane, tris(3-methyldimethoxysilylpropyl)isocyanurate, [hydroxy(polyethyleneoxy)propyl]methyl diethoxysilane, N,N′-bis(hydroxyethyl)-N,N′-bis(methyldimethoxysilylpropyl)ethylenediamine, bis-[3-(methyldiethoxysilylpropyl)-2-hydroxypropoxy]polyethylene oxide, bis[N,N′-(methyl-diethoxysilylpropyl)aminocarbonyl]polyethylene oxide, bis(methyldiethoxysilylpropyl)polyethylene oxide. Among the above, particularly preferable example include dimethyl dimethoxysilane, diethyl dimethoxysilane, dimethyl diethoxysilane, diethyl diethoxysilane, and the like from the viewpoints of easy procurement and adhesion to hydrophilic layers.

In a case in which M³ is Si and a is 3, that is, a trifunctional organo alkoxysilane can be, for example, methyl trimethoxysilane, ethyl trimethoxysilane, propyl trimethoxysilane, methyl triethoxysilane, ethyl triethoxysilane, propyl triethoxysilane, γ-chloropropyl triethoxysilane, γ-chloropropyl trimethoxysilane, chloromethyl triethoxysilane, (p-chloromethyl)phenyl trimethoxy silane, γ-bromopropyl trimethoxysilane, acetoxymethyl triethoxysilane, acetoxymethyl trimethoxysilane, acetoxypropyl trimethoxy silane, benzoyloxypropyl trimethoxysilane, 2-(carbomethoxy)ethyl trimethoxysilane, phenyl trimethoxysilane, phenyl triethoxysilane, phenyl tripropoxysilane, hydroxymethyl triethoxysilane, N-(triethoxysilylpropyl)-O-polyethylene oxido urethane, N-(3-triethoxysilylpropyl)-4-hydroxybutyl amide, N-(3-triethoxysilylpropyl)gluconamide, vinyl trimethoxysilane, vinyl triethoxysilane, vinyl tributoxysilane, isopropenyl trimethoxysilane, isopropenyl triethoxysilane, isopropenyl tributoxysilane, vinyl tris(2-methoxyethoxy)silane, allyl trimethoxysilane, vinyldecyl trimethoxy silane, vinyloctyl trimethoxysilane, vinylphenyl trimethoxysilane, isopropenylphenyl trimethoxysilane, 2-(meth)acryloyloxyethyl trimethoxysilane, 2-(meth)acryloyloxyethyl triethoxysilane, 3-(meth)acryloyloxypropyl trimethoxysilane, 3-(meth)acryloyloxypropyl trimethoxysilane, 3-(meth)acryloyloxypropyl tris(2-methoxyethoxy)silane, 3-[2-(allyloxycarbonyl)phenylcarbonyloxy]propyl trimethoxysilane, 3-(vinylphenylamino)propyl trimethoxysilane, 3-(vinylphenylamino)propyl triethoxysilane, 3-(vinylbenzylamino)propyl triethoxysilane, 3-(vinylbenzylamino)propyl triethoxysilane, 3-[2-(N-vinylphenylmethylamino)ethylamino]propyl trimethoxysilane, 3-[2-(N-isopropenylphenylmethylamino)ethylamino]propyl trimethoxysilane, 2-(vinyloxy)ethyl trimethoxysilane, 3-(vinyloxy)propyl trimethoxysilane, 4-(vinyloxy)butyl triethoxysilane, 2-(isopropenyloxy)ethyl trimethoxysilane, 3-(allyloxy)propyl trimethoxysilane, 10-(allyloxycarbonyl)decyl trimethoxysilane, 3-(isopropenyl methyloxy)propyl trimethoxysilane, 10-(isopropenylmethyloxycarbonyl)decyl trimethoxysilane, 3-[(meth)acryloyloxy]propyl trimethoxysilane, 3-[(meth)acryloyloxy]propyl triethoxysilane, (meth)acryloyloxymethyl trimethoxysilane, (meth)acryloyloxymethyl triethoxysilane, γ-glycidoxypropyl trimethoxysilane, N-[3-(meth)acryloyloxy-2-hydroxypropyl]-3-aminopropyl triethoxysilane, O-[(meth)acryloyloxyethyl]-N-(triethoxysilylpropyl)urethane, γ-glycidoxypropyl triethoxysilane, β-(3,4-epoxycyclohexyl)ethyl trimethoxysilane, γ-aminopropyl triethoxysilane, γ-aminopropyl trimethoxysilane, 4-aminobutyl triethoxysilane, 11-aminoundecyl triethoxysilane, m-aminophenyl trimethoxysilane, p-aminophenyl trimethoxysilane, 3-amino propyl tris(methoxyethoxyethoxy)silane, 2-(4-pyridyl)ethyl triethoxysilane, 2-(trimethoxysilylethyl)pyridine, N-(3-trimethoxysilylpropyl)pyrrole, 3-(m-amino-phenoxy)propyl trimethoxysilane, N-(2-aminoethyl)-3-aminopropyl trimethoxysilane, N-(2-aminoethyl)-3-aminopropyl triethoxysilane, N-(6-aminohexyl)aminomethyl triethoxy silane, N-(6-aminohexyl)aminopropyl trimethoxysilane, N-(2-aminoethyl)-11-aminoundecyl trimethoxysilane, (aminoethylaminomethyl)phenethyl trimethoxysilane, 3-N-[(amino(polypropyleneoxy))]aminopropyl trimethoxysilane, n-butylaminopropyl trimethoxy silane, N-ethylaminoisobutyl trimethoxy silane, N-methylaminopropyl trimethoxysilane, N-phenyl-γ-aminopropyl trimethoxysilane, N-phenyl-γ-aminomethyl triethoxysilane, (cyclohexylaminomethyl)triethoxysilane, N-cyclohexylaminopropyl trimethoxysilane, bis(2-hydroxyethyl)-3-aminopropyl triethoxysilane, diethylaminomethyl triethoxysilane, diethylaminopropyl trimethoxy silane, dimethylaminopropyl trimethoxysilane, N-3-trimethoxysilylpropyl-m-phenylenediamine, N,N-bis[3-(trimethoxysilyl)propyl]ethylenediamine, bis(triethoxysilylpropyl)amine, bis(trimethoxysilylpropyl)amine, bis[(3-trimethoxysilyl)propyl]-ethylenediamine, bis[3-(triethoxysilyl)propyl]urea, bis(trimethoxysilylpropyl)urea, N-(3-triethoxysilylpropyl)-4,5-dihydroimidazole, ureidopropyltriethoxysilane, ureidopropyltrimethoxysilane, acetamidopropyl trimethoxysilane, 2-(2-pyridylethyl)thiopropyl trimethoxysilane, 2-(4-pyridylethyl)thiopropyl trimethoxysilane, bis[3-(triethoxysilyl)propyl]disulfide, 3-(triethoxysilyl)propylsuccinic acid anhydride, γ-mercaptopropyl trimethoxysilane, γ-mercaptopropyl triethoxysilane, isocyanatopropyl trimethoxysilane, isocyanatopropyl triethoxysilane, isocyanatoethyl triethoxysilane, isocyanatomethyl triethoxysilane, carboxyethylsilanetriol sodium salt, N-(trimethoxysilyl propyl)ethylenediamine triacetic acid trisodium salt, 3-(trihydroxysilyl)-1-propanesulfonic acid, diethyl phosphatoethyl triethoxysilane, 3-trihydroxysilylpropyl methyl phosphonate sodium salt, bis(triethoxysilyl)ethane, bis(trimethoxysilyl)ethane, bis(triethoxysilyl)methane, 1,6-bis(triethoxysilyl)hexane, 1,8-bis(triethoxysilyl)octane, p-bis(trimethoxysilylethyl)benzene, p-bis(trimethoxysilyl)methylbenzene, 3-methoxypropyl trimethoxysilane, 2-[methoxy(polyethyleneoxy)propyl]trimethoxysilane, methoxytriethyleneoxypropyl trimethoxysilane, tris(3-trimethoxysilylpropyl)isocyanurate, [hydroxy(polyethyleneoxy)propyl]triethoxysilane, N,N′-bis(hydroxyethyl)-N,N′-bis(trimethoxysilylpropyl)ethylenediamine, bis[3-(triethoxysilylpropyl)-2-hydroxypropoxy]polyethylene oxide, bis[N,N′-(triethoxysilylpropyl)aminocarbonyl]polyethylene oxide, bis(triethoxysilylpropyl)polyethylene oxide. Among the above, methyl trimethoxysilane, ethyl trimethoxysilane, methyl triethoxysilane, ethyl triethoxysilane, 3-glycidoxypropyl trimethoxysilane and the like are particularly preferable from the viewpoints of easy procurement and adhesion to a hydrophilic layer.

In a case in which M² is Ti and a is 2, that is, a difunctional organo alkoxy titanate can be, for example, dimethyl dimethoxy titanate, diethyl dimethoxy titanate, propyl methyl dimethoxy titanate, dimethyl diethoxy titanate, diethyl diethoxy titanate, dipropyl diethoxy titanate, phenyl ethyl diethoxy titanate, phenyl methyl dipropoxy titanate, dimethyl dipropoxy titanate or the like.

In a case in which M² is Ti and a is 3, that is, a trifunctional organo alkoxy titanate can be, for example, methyl trimethoxy titanate, ethyl trimethoxy titanate, propyl trimethoxy titanate, methyl triethoxy titanate, ethyl triethoxy titanate, propyl triethoxy titanate, chloromethyl triethoxy titanate, phenyl trimethoxy titanate, phenyltriethoxy titanate, phenyl tripropoxy titanate or the like.

In a case in which M² is Zr, that is, bifunctional and trifunctional organoalkoxy zirconates can be, for example, organoalkoxy zirconates obtained by changing Ti into Zr in the compounds exemplified as the bifunctional and trifunctional organoalkoxy titanates.

The tetraalkoxy compounds and the organoalkoxy compounds can be easily procured from commercially available products, and also can be obtained using a well-known synthesis method, for example, a reaction between a metal halide and an alcohol.

Each of the tetraalkoxy compounds and the organoalkoxy compounds may be solely used, or a combination of two or more compounds may be used.

Particularly preferable examples of the tetraalkoxy compounds include tetramethoxysilane, tetraethoxysilane, tetrapropoxy titanates, tetraisopropoxy titanates, tetraethoxy zirconates, tetrapropoxy zirconates and the like. In addition, particularly preferable examples of the organoalkoxy compounds include 3-glycidoxypropyl trimethoxysilane, 2-(3,4-epoxycyclohexyl)ethyl trimethoxysilane, ureidopropyl triethoxysilane, diethyldimethoxysilane, propyl triethoxytitanates, ethyl triethoxy zirconates and the like.

As described above, the cured sol-gel substance as the component (ii) that configures the conductive layer is a substance obtained by hydrolyzing and polycondensing a combination of the tetraalkoxy compound represented by Formula (I) and the organoalkoxy compound represented by Formula (II). Thereby, a conductive member which has high conduction, high transparency and high film strength, and is excellent in terms of abrasion resistance and bending resistance compared with a conductive member with a conductive layer including a cured sol-gel substance obtained by solely hydrolyzing and polycondensing the tetraalkoxy compound or the organoalkoxy compound together with the metallic nanowires is obtained. The reason is assumed that, since the cured sol-gel substance as the component (ii) that configures the conductive layer includes a group derived from R³ in Formula (II) in the three-dimensional crosslinked structure including a substructure represented by -M-O-M- (here, M represents an element selected from a group consisting of Si, Ti and Zr), the flexibility of the conductive layer improves, and thereby the characteristics of excellent bending resistance and excellent abrasion resistance are obtained.

It is advantageous to select the mass ratio (tetraalkoxy compound/organoalkoxy compound) of the content of the tetraalkoxy compound to the content of the organoalkoxy compound in the conductive layer in a range of from 0.01/1 to 100/1, more preferably in a range of 0.02/1 to 50/1, and still more preferably in a range of 0.05/1 to 20/1 since a conductive member that is excellent in terms of film strength, abrasion resistance and bending resistance can be easily obtained.

The mass ratio (that is, the mass ratio of the total content of the tetraalkoxy compound and the organoalkoxy compound as the raw materials of the cured sol-gel substance to the content of the metallic nanowires) of the content of the cured sol-gel substance to the content of the metallic nanowires in the conductive layer is preferably in a range of 0.5/1 to 25/1, more preferably in a range of 1/1 to 20/1, and still more preferably in a range of 2/1 to 15/1 since a conductive layer which has high conduction, high transparency and high film strength, and is excellent in terms of abrasion resistance, heat resistance, moisture and heat resistance and bendability can be easily obtained.

<<<Production Method of the Conductive Member>>>

In an embodiment, the conductive member can be produced using a method including at least the formation of a liquid film by supplying a liquid composition (hereinafter, also referred to as “sol-gel coating liquid”) containing the metallic nanowires having an average short-axis length of 150 nm or less and the tetraalkoxy compound and the organoalkoxy compound (hereinafter, a substance made up of both compounds will also be referred to as “specific alkoxide compound”) to a base material, and the formation of a conductive layer by causing a reaction of the hydrolysis and polycondensation (or condensation) (hereinafter, the reaction of the hydrolysis and polycondensation (or condensation) will also be referred to as “sol-gel reaction”) of the specific alkoxide compound in the liquid film. The method may or may not further include the vaporization of water that can be included in the liquid composition as a solvent by heating (drying) as necessary.

In an embodiment, the sol-gel coating liquid may be prepared by preparing a metallic nanowire aqueous dispersion liquid, and mixing the water and the specific alkoxide compound therewith. In an embodiment, the sol-gel coating liquid may be prepared by preparing an aqueous solution containing the specific alkoxide compound, heating the aqueous solution so as to hydrolyze and polycondense at least a part of the specific alkoxide compound and turn the part of the specific alkoxide compound into a sol state, and mixing the aqueous solution in the sol state and the metallic nanowire aqueous dispersion liquid.

It is practically preferable to jointly use an acidic catalyst or a basic catalyst in order to accelerate the sol-gel reaction since the reaction efficiency increases. Hereinafter, the catalyst will be described.

[Catalyst]

The liquid composition that forms the conductive layer preferably includes at least one catalyst that accelerates the sol-gel reaction. The catalyst is not particularly limited as long as the catalyst accelerates the reaction of the hydrolysis and polycondensation of the tetraalkoxy compound and the organoalkoxy compound, and the catalyst can be appropriately selected from ordinarily-used catalysts.

Examples of the catalyst include acidic compounds and basic compounds. The acidic compounds and the basic compounds can be used as they are, and may be used in a state in which the compounds are dissolved in a solvent such as water or an alcohol (hereinafter, also referred to as acidic catalysts and basic catalyst respectively including the compounds dissolved in a solvent).

The concentration of the acidic compound or the basic compound dissolved in the solvent is not particularly limited, and may be appropriately selected depending on the characteristics of the acidic compound or the basic compound being used, the desired content of the catalyst and the like. Here, in a case in which the concentration of the acidic or basic compound that constitutes the catalyst is high, there is a tendency of the rate of the hydrolysis and polycondensation increasing. However, when a basic catalyst with an excessively high concentration is used, since there are cases in which sediment is generated and appears as defects in a layer, in a case in which the basic catalyst is used, the concentration is desirably 1 N or less in terms of the concentration in a liquid composition.

The kind of the acidic catalyst or the basic catalyst is not particularly limited; however, in a case in which it is necessary to use a catalyst having a high concentration, it is preferable to select a catalyst made of an element that rarely remains in the conductive layer. Specific examples of the acidic catalyst include hydrogen halides such as hydrochloric acid; inorganic acids such as nitric acid, sulfuric acid, sulfurous acid, hydrogen sulfide, perchloric acid, hydrogen perchloride and carbonic acid; carboxylic acids such as formic acid and acetic acid; substituted carboxylic acids in which R in a structural formula represented by RCOOH has a substituent; sulfonic acids such as benzenesulfonic acid; and the like, and specific examples of the basic catalyst include quaternary ammonium salt compounds such as ammonia water and tetramethylammonium hydroxide; organic amines such as ethylamine and aniline; and the like.

Here, R represents a hydrocarbon group. The hydrocarbon group represented by R has the same definition as the hydrocarbon group in the Formula (II), and has the same preferable embodiments.

As the catalyst, Lewis acid catalysts made of a metallic complex can also be preferably used. Particularly preferable catalysts are metallic complex catalysts, and examples thereof include metallic complexes made up of a metallic element selected from Groups 2A, 3B, 4A and 5A of the periodic table and a ligand that is an oxo or hydroxyl oxygen-containing compound selected from a group consisting of β-diketones, ketoesters, hydroxyl carboxylic acids or esters thereof, almino alcohols and enolic active hydrogen compounds.

Among the constituent metallic elements, elements belonging to Group 2A such as Mg, Ca, Sr and Ba; elements belonging to Group 3B such as Al and Ga; elements belonging to Group 4A such as Ti and Zr; and elements belonging to Group 5A such as V, Nb and Ta are preferable, and each of the above elements forms a complex having an excellent catalytic effect. Among the above, complexes including a metallic element selected from a group consisting of Zr, Al and Ti are excellent and preferable.

Specific examples of the oxo or hydroxyl oxygen-containing compound that forms the ligand of the metallic complex include β-diketones such as acetylacetone (2,4-pentanedione) and 2,4-heptanedione; keto esters such as methyl acetoacetate, ethyl acetoacetate, and butyl acetoacetate; hydroxyl carboxylic acids such as lactic acid, methyl lactate, salicylic acid, ethyl salicylate, phenyl salicylate, malic acid, tartaric acid and methyl tartrate; keto alcohols such as 4-hydroxy-4-methyl-2-pentanone, 4-hydroxy-2-pentanone, 4-hydroxy-4-methyl-2-heptanone and 4-hydroxy-2-heptanone; amino alcohols such as monoethanolamine, N,N-dimethylethanolamine, N-methylmonoethanolamine, diethanolamine and triethanolamine; enolic active compounds such as methylolmelamine, methylolurea, methylolacrylamide and diethyl malonate ester; acetylacetone derivatives having a substituent at a methyl group, a methylene group or carbonyl carbon of acetylacetone (2,4-pentanedione); and the like.

A preferable ligand is an acetylacetone derivative. Here, the acetylacetone derivative refers to a compound having a substituent at a methyl group, a methylene group or carbonyl carbon of acetylacetone. Examples of the substituent that substitutes the methyl group of acetylacetone include linear or branched alkyl groups, acyl groups, hydroxyalkyl groups, carboxyalkyl groups, alkoxy groups and alkoxyalkyl groups all of which have 1 to 3 carbon atoms; examples of the substituent that substitutes the methylene group of acetylacetone include linear or branched carboxyalkyl groups and hydroxyalkyl groups all of which have 1 to 3 carbon atoms, and examples of the substituent that substitutes the carbonyl carbon of acetylacetone include alkyl groups having 1 to 3 carbon atoms, in which a hydrogen atom is added to the carbonyl oxygen so as to form a hydroxyl group.

Specific examples of preferable acetylacetone derivatives include ethylcarbonylacetone, n-propylcarbonylacetone, i-propylcarbonylacetone, di-acetylacetone, 1-acetyl-1-propionyl-acetylacetone, hydroxyethylcarbonylacetone, hydroxypropylcarbonyl acetone, acetoacetic acid, acetopropionic acid, diacetoacetic acid, 3,3-diacetopropionic acid, 4,4-diacetobutyric acid, carboxyethylcarbonylacetone, carboxypropylcarbonylacetone, and diacetone alcohol. Among the above, acetylacetone and diacetylacetone are particularly preferable. The acetylacetone derivatives and the complexes of the above metallic element are mononuclear complexes in which one metallic element is coordinated with 1 to 4 acetylacetone derivatives, and, in a case in which the number of possible coordinate bonds of the metallic element is larger than the total number of possible coordinate bonds of the acetylacetone derivatives, the metallic element may be coordinated with ligands that are ordinarily used in complexes, such as water molecules, halogen ions, nitro groups and ammonio groups.

Preferable examples of the metallic complex include tris(acetylacetonato) aluminum complex salts, di(acetylacetonato) aluminum•aquo complex salts, mono(acetylacetonato) aluminum•chloro complex salts, di(diacetylacetonato) aluminum complex salts, ethyl acetoacetate aluminum diisopropylate, aluminum tris(ethyl acetoacetate), cyclic aluminum oxide isopropylate, tris(acetylacetonato) barium complex salts, di(acetylacetonato) titanium complex salts, tris(acetylacetonato) titanium complex salts, di-i-propoxy•bis(acetylacetonato) titanium complex salts, zirconium tris(ethyl acetoacetate), zirconium tris(benzoic acid) complex salts, and the like. The above metallic complexes are excellent in terms of stability in aqueous coating liquids and a gelation acceleration effect in sol-gel reactions during heating and drying, and, among the above, ethyl acetoacetate aluminum diisopropylate, aluminum tris(ethyl acetoacetate), di(acetylacetonato) titanium complex salts, zirconium tris(ethyl acetoacetate) are particularly preferable.

The counter ions of the above metallic complexes will not be described in detail. The kind of counter ion is arbitrary as long as the counter ion forms a water-soluble salt that can maintain the electrical neutrality of the complex compound, and, for example, nitrate, halogen acid salts, sulfate, phosphate and the like can be used in a form of a salt that can ensure stoichiometric neutrality.

The behaviors of the metallic complexes in silica sol-gel reactions are described in detail in J. Sol-Gel. Sci. and Tec., Vol. 16, pp. 209 to 220 (1999). The following scheme is assumed as a reaction mechanism. That is, in a liquid composition, the metallic complex is stable in a coordinate structure. In a dehydration condensation reaction which begins in a natural drying or heating and drying process after the conductive layer is supplied to the base material, it is considered that crosslinking is accelerated in a mechanism similar to that of the acidic catalyst. In any cases, the use of the metallic complex enables the obtainment of a matrix that is excellent in terms of the stability of the liquid composition over time, and the coat surface qualities and high durability of the conductive layer.

In a case in which the liquid composition contains the catalyst, the catalyst is used in a range of preferably 50% by mass or less and more preferably from 5% by mass to 25% by mass with respect to the solid content of the liquid composition. The catalyst may be solely used, or may be used in a combination of two or more catalysts.

[Solvent]

The liquid composition may contain water and/or an organic solvent as necessary. When the liquid composition contains an organic solvent, a more uniform liquid film can be formed. Examples of the organic solvent include ketone-based solvents such as acetone, methyl ethyl ketone and diethyl ketone; alcohol-based solvents such as methanol, ethanol, 2-propanol, 1-propanol, 1-butanol and tert-butanol; chlorine-based solvents such as chloroform and methylene chloride; aromatic solvents such as benzene and toluene; ester-based solvents such as ethyl acetate, butyl acetate and isopropyl acetate; ether-based solvents such as diethyl ether, tetrahydrofuran and dioxane; glycol ether-based solvents such as ethylene glycol monomethyl ether and ethylene glycol dimethyl ether; and the like.

In a case where the liquid composition contains an organic solvent, a content of the organic solvent is preferably in a range of 50% by mass or less and more preferably 30% by mass or less with respect to the total mass of the liquid composition.

In the coated liquid film of the sol-gel coating liquid formed on the base material, the reaction of the hydrolysis and polycondensation of the specific alkoxide compound occurs, and the coated liquid film is preferably heated and dried in order to accelerate the reaction. The heating temperature for accelerating the sol-gel reaction is appropriately in a range of 30° C. to 200° C., and more preferably in a range of 50° C. to 180° C. The heating and drying time is preferably 10 seconds to 300 minutes, and more preferably 1 minute to 120 minutes.

The average film thickness of the conductive layer is preferably 0.005 μm to 0.5 μm, more preferably 0.007 μm to 0.3 μm, still more preferably 0.008 μm to 0.2 μm, and particularly preferably 0.01 μm to 0.1 μm. When the average film thickness is set to 0.005 μm to 0.5 μm, sufficient durability and sufficient film strength can be obtained. Furthermore, it is possible to sufficiently remove metallic nanowires in the non-conductive area when the conductive layer is patterned into the conductive area and the non-conductive area. Moreover, it is particularly preferable to set the average film thickness in a range of from 0.01 μm to 0.1 μm since the production allowance can be ensured.

The average film thickness of the conductive layer is computed in a form of an arithmetic average value after measuring the film thickness of the conductive layer at five points through the direct observation of the cross-section of the conductive layer using en electronic microscope. The average film thickness is computed by measuring the thickness of only the matrix component in which the metallic nanowires are not present. Meanwhile, the film thickness of the conductive layer can also be measured from the difference in thickness between a conductive layer-formed portion and a conductive layer-removed portion using a stylus type surface profiler DEKTAK 150 (trade name, manufactured by ULVAC, Inc.). However, there is a concern that some of the base material may be removed when removing the conductive layer, and an error may be easily caused since the conductive layer being formed is a thin film. Therefore, in examples described below, the average film thickness measured by using an electronic microscope will be adopted.

The water droplet contact angle on a surface (hereinafter, also referred to as “outer surface”) of the conductive layer opposite to the surface facing the base material is preferably from 3° to 70°, more preferably from 5° to 60°, still more preferably from 5° to 50°, and most preferably from 5° to 40°. When the water droplet contact angle on the surface of the conductive layer is in the above range, the etching speed in a patterning method in which an etchant (etching liquid) described below is used tends to improve. This can be considered to be because, for example, the etchant can be easily incorporated into the conductive layer. In addition, there is a tendency for the accuracy of the line widths of patterned fine lines to improve. Furthermore, in a case in which wires are formed on the conductive layer using a silver paste, the adhesiveness between the conductive layer and the silver paste tends to improve.

Meanwhile, the water droplet contact angle on the outer surface of the conductive layer is measured at 25° C. using a contact angle meter (for example, an automatic contact angle meter DM-701; trade name, manufactured by KYOWA INTERFACE SCIENCE Co., Ltd.).

The water droplet contact angle on the surface of the conductive layer can be set in a desired range by appropriately selecting the kind of the alkoxide compound, the condensation degree of the alkoxide compound, the flatness of the conductive layer, and the like in the liquid composition.

The surface resistivity of the conductive layer is preferably 1,000Ω/□ or less. Here, the surface resistivity of the conductive layer refers to the surface resistivity in the conductive area in a case in which the conductive layer includes the non-conductive area and the conductive area.

The surface resistivity is a value obtained by measuring the surface of the conductive layer on the opposite side to the base material side in the conductive member using a four-point probe method. The measurement method for the surface resistivity using the four-point probe method can be carried out based on JIS K 7194:1994 (testing method for resistivity of conductive plastics with a four-point probe array) and the like, and the surface resistivity can be easily measured using a commercially available surface resistivity meter. In order to set the surface resistivity to 1,000Ω/□ or less, it is necessary to adjust at least one of the kind and the content rate of the metallic nanowires in the conductive layer. More specifically, when the content ratio of the specific alkoxide compound to the metallic nanowires is adjusted to a mass ratio in a range of from 0.25/1 to 30/1, a conductive layer having a surface resistivity in a desired range can be formed.

The surface resistivity of the conductive layer is more preferably in a range of from 0.1Ω/□ to 900 Ω/□.

The shape of the conductive layer observed from a direction vertical to the surface of the base material in the conductive member is not particularly limited, and can be appropriately selected depending on the purpose. The conductive layer may include a non-conductive area. That is, the conductive layer may be a first aspect in which the entire area of the conductive layer is a conductive area (hereinafter, the conductive layer will also be referred to as “non-patterned conductive layer”) and a second aspect in which the conductive layer includes a conductive area and a non-conductive area (hereinafter, the conductive layer will also be referred to as “patterned conductive layer”). In the case of the second aspect, the metallic nanowires may or may not be included in the non-conductive area. In a case in which the metallic nanowires are included in the non-conductive area, the metallic nanowires in the non-conductive area are cut.

The conductive member according to the first aspect can be used in, for example, a transparent electrode of a solar cell.

The conductive member according to the second aspect can be used to, for example, configure a touch panel. In this case, a conductive area and a non-conductive area with desired shapes are formed.

The surface resistivity of the non-conductive area is not particularly limited. The surface resistivity is preferably 1.0×10⁷Ω/□ or more, and more preferably 1.0×10⁸Ω/□ or more. The surface resistivity of the conductive area is preferably 1.0×10³Ω/□ or less, and more preferably 9.0×10²Ω/□ or less.

The patterned conductive layer is produced using, for example, the following patterning method.

(1) A patterning method in which a non-patterned conductive layer is formed in advance, high-energy laser rays such as carbonate gas lasers or YAG lasers are radiated on metallic nanowires included in desired area in the non-patterned conductive layer so as to cut or remove some of the metallic nanowires, thereby forming the desired area into a non-conductive area. The present method is described in, for example, JP-A No. 2010-44968.

(2) A patterning method in which a photosensitive composition (photoresist) layer that can form a resist layer on a preformed non-patterned conductive layer is provided, desired pattern exposure and development are carried out on the photosensitive composition layer so as to form a resist layer in the pattern, and then a wet process for treating the resist layer using an etchant that can dissolve metallic nanowires or a dry process such as reactive ion etching is carried out, thereby removing metallic nanowires in the conductive layer not protected by the resist layer through etching. The present method is described in, for example, JP-A No. 2010-507199 (particularly, Paragraphs [0212] to [0217]).

(3) A patterning method in which an etchant that can dissolve metallic nanowires is supplied to a preformed non-patterned conductive layer in a desired shape, thereby removing metallic nanowires in the conductive layer in an area supplied with the etchant through etching.

A light source used for the pattern exposure of the photosensitive composition layer is selected in consideration of the photosensitive wavelength range of the photosensitive composition, and, in general, ultraviolet rays such as g rays, h rays, i rays or j rays are preferably used. In addition, a blue LED may also be used.

The pattern exposure method is also not particularly limited, and may be carried out through surface exposure using a photomask or through scanning exposure using laser beams or the like. At this time, the pattern exposure method may be refraction exposure using a lens or reflection exposure using a reflecting mirror, and exposure methods such as contact exposure, proximity exposure, reduction projection exposure, and reflection projection exposure can be used.

The supply method of the etchant that can dissolve the metallic nanowires is not particularly limited, and can be appropriately selected depending on the purpose. Examples thereof include screen printing, an ink jet method, coater coating, roller coating, dip (immersion) coating, a spray coating method, and the like. Among the above, screen printing, an ink jet method, coater coating, and dip coating are particularly preferable.

The supply method of the etchant in a desired pattern is not particularly limited, and can be appropriately selected depending on the purpose. Examples thereof include screen printing, an ink jet method and the like.

As the ink jet method, for example, any one of a piezo method and a thermal method can be used.

The kind of the pattern is not particularly limited, and can be appropriately selected depending on the purpose. Examples thereof include letters, symbols, designed patterns, figures, wire patterns, and the like.

The size of the pattern is not particularly limited, can be appropriately selected depending on the purpose, and may be any one in a range of nanometer size to millimeter size.

The etchant that can dissolve the metallic nanowires can be appropriately selected depending on the kind of the metallic nanowires. For example, in a case in which the metallic nanowires are silver nanowires, a bleach-fixing solution, a strong acid, an oxidant, hydrogen peroxide or the like which is mainly used in the bleaching and fixing step of photographic paper of silver halide color photosensitive materials in the so-called photographic science field can be selected. Among the above, a bleach-fixing solution, diluted nitric acid, and hydrogen peroxide are particularly preferable. In the dissolution of metallic nanowires using the etchant, metallic nanowires in portions to which the etchant has been supplied may not be fully dissolved, and some of the metallic nanowires may remain if the conduction is lost.

The concentration of the diluted nitric acid is preferably from 1% by mass to 20% by mass.

The concentration of the hydrogen peroxide is preferably from 3% by mass to 30% by mass.

As the bleach-fixing solution, treatment materials or treatment methods described in, for example, Row 1 in the lower right column on Page 26 to Row 9 in the upper right column on Page 34 in JP-A No. H2-207250 and Row 17 in the upper left column on Page 5 to Row 20 in the lower right column on Page 18 in JP-A No. H4-97355 can be preferably applied.

A bleach-fixing time is preferably 180 seconds or less, practically more preferably from 1 second to 120 seconds, practically more preferably from 2 seconds to 60 seconds, and practically most preferably from 5 seconds to 30 seconds. In addition, the water washing or stabilizing time is preferably 180 seconds or less, more preferably from 1 second to 120 seconds, and even more preferably from 5 second to 90 seconds.

The bleach-fixing liquid is not particularly limited as long as the bleach-fixing liquid is for photographic use, and can be appropriately selected depending on the purpose. Examples thereof include CP-48S, CP-49E (all trade name, bleach-fixing agents for color paper) manufactured by FUJIFILM Corporation, EKTACOLOR RA; trade name, bleach-fixing solution manufactured by KODAK Corporation, bleach-fixing solutions D-J2P-02-P2, D-30P2R-01, D-22P2R-01; all trade name, manufactured by DAI NIPPON PRINTING Co., Ltd. and the like. Among the above, CP-48S and CP-49E are particularly preferable.

A viscosity of the etching liquid that dissolves the metallic nanowires is preferably from 5 mPa·s to 300,000 mPa·s, and more preferably from 10 mPa·s to 150,000 mPa·s at 25° C. When the viscosity is set to 5 mPa·s, it becomes easy to control the diffusion of the etching liquid in a desired range so that formation of a pattern having a clear boundary between a conductive area and a non-conductive area is ensured, and, on the other hand, when the viscosity is set to 300,000 mPa·s or less, it is possible to ensure the printing of the etching liquid with no load and to adjust the treatment time necessary for the dissolution of the metallic nanowires in a desired time range.

Since the conductive layer in the conductive member is excellent in terms of etching characteristics, it is preferable that the conductive layer in the conductive member include a non-conductive area and a conductive area, at least the conductive area include the metallic nanowires, and the non-conductive area be formed by supplying the etchant that dissolves the metallic nanowires.

The forming method of the non-conductive area by supplying the etchant may be a method in which the etchant is supplied to the conductive layer in a patterned shape. The forming method may be, for example, a method in which the etchant is supplied in a patterned shape using a resist layer, or a method in which the etchant is supplied in a patterned shape using screen printing, an ink jet method or the like. From the viewpoint of productivity, the formation method is preferably a method in which the etchant is supplied in a patterned shape using screen printing, an ink jet method or the like.

<Matrix>

The conductive layer may include a matrix. Here, the “matrix” is a collective term for substances that include the metallic nanowires so as to form a layer. When the conductive layer includes the matrix, the dispersion of the metallic nanowires in the conductive layer is stably maintained, and therefore the base material and the conductive layer tend to be strongly adhered even in a case in which the conductive layer is formed on the surface of the base material without the adhesion layer. The cured sol-gel substance in the conductive layer also functions as the matrix, the conductive layer may further include matrixes other than the cured sol-gel substance (hereinafter, referred to as “other matrixes”). The conductive layer including other matrixes may contain a material that can form other matrixes or other matrixes may be formed by supplying the material to the base material (through, for example, coating).

Other matrixes may be a non-photosensitive substance such as an organic macromolecular polymer or a photosensitive substance such as a photoresist composition.

In a case in which the conductive layer includes other matrixes, it is advantageous to select the content of other matrixes in a range of 0.10% by mass to 20% by mass, preferably 0.15% by mass to 10% by mass, and more preferably 0.20% by mass to 5% by mass with respect to the content of the cured sol-gel substance derived from the specific alkoxy compound in the conductive layer since a conductive member that is excellent in terms of conduction, transparency, film strength, abrasion resistance and bending resistance can be obtained.

Other matrixes may be a non-photosensitive substance or a photosensitive substance as described above.

Examples of appropriate non-photosensitive matrix include organic macromolecular polymers. Specific examples of the organic macromolecular polymers include polyacrylics such as polyacrylic acid, polymethacrylates (for example, poly methyl methacrylate), polyacrylates, polyacrylonitrile, and the like; polyvinyl alcohols; polyesters (for example, polyethylene terephthalate (PET), polyethylene naphthalate, polycarbonates and the like); highly aromatic macromolecules such as phenol or cresol-formaldehyde (NOVOLACS (registered trademark)), polystyrene, polyvinyl toluene, polyvinyl xylene, polyimides, polyamide, polyamide-imides, polyether imides, polysulfides, polysulfones, polyphenylene and polyphenyl ethers, and the like; polyurethane (PU); epoxy resins; polyolefins (for example, polypropylene, polymethyl pentene and cyclic olefins); acrylonitrile-butadiene-styrene copolymers (ABS); celluloses, silicones and other silicon-containing macromolecules (for example, polysilsesquioxane and polysilanes); polyvinyl chlorides (PVC); polyvinyl acetates; polynorbornenes; synthetic rubber (for example, EPR, SBR, EPDM); carbon fluoride polymers (for example, polyvinylidene fluoride, polytetrafluoroethylene (PTFE) and polyhexafluoropropylene, copolymers of fluoroolefins (for example, “LUMIFLON” (registered trademark) manufactured by ASAHI GLASS Co., Ltd.), and amorphous fluorocarbon polymers or copolymers (for example, “CYTOP” (registered trademark) manufactured by ASAHI GLASS Co., Ltd.), “TEFLON” (registered trademark) AF manufactured by Du Pont KABUSHIKI KAISHA, and the like).

A photoresist composition that is preferable for lithography processes can be included as the photosensitive matrix. In a case in which a photoresist composition is included as the matrix, it becomes possible to form a conductive layer including a conductive area and a non-conductive area in a patterned shape using a lithographic process. Among the above photoresist compositions, a photopolymerizable composition is particularly preferable since a conductive layer that is excellent in terms of transparency, flexibility, adhesiveness with the base material can be obtained. Hereinafter, the photopolymerizable composition will be described.

<Photopolymerizable Composition>

The photopolymerizable composition includes (a) an addition polymerizable unsaturated compound and (b) a photopolymerization initiator that generates radicals when irradiated with light as basic components. The photopolymerizable composition may further include (c) a binder and/or (d) additives other than the components (a) to (c) as desired.

Hereinafter, the components will be described.

[(a) Addition Polymerizable Unsaturated Compound]

The addition polymerizable unsaturated compound (hereinafter, also referred to as “polymerizable compound”) of the component (a) is a compound polymerized by causing an addition polymerization reaction in the presence of a radical, and, generally, a compound having at least one, preferably two or more, more preferably four or more, and still more preferably six or more ethylenically unsaturated double bonds at the molecular terminal is used.

The compound has a chemical form, for example, a monomer, a prepolymer, that is, a dimer, a trimer or an oligomer, or a mixture thereof.

A variety of polymerizable compounds are known, and the compounds can be used as the component (a).

Among the above, the polymerizable compound is particularly preferably trimethylol propane tri(meth)acrylate, pentaerythritol tetra(meth)acrylate, dipentaerythritol hexa(meth)acrylate, dipentaerythritol penta(meth)acrylate from the viewpoint of film strength.

The content of the component (a) in the conductive layer is preferably from 2.6% by mass to 37.5% by mass, and more preferably from 5.0% by mass to 20.0% by mass with respect to the total mass of the solid content of the photopolymerizable composition including the metallic nanowires.

[(b) Photopolymerization Initiator]

The photopolymerization initiator of the component (b) is a compound that generates radicals when irradiated with light. Examples of the photopolymerization initiator include compounds that generate acidic radicals that eventually become acids by light radiation, compounds that generate other radicals, and the like. Hereinafter, the former will be called “photo acid-generating agent” and the latter will be called “photo radical-generating agent”.

—Photo Acid-Generating Agent—

The photo acid-generating agent can be appropriately selected and used from photoinitiators of photo-cationic polymerization, photoinitiators of photo-radical polymerization, photo-decoloring agents of colorants, photo-discoloring agents, well-known compounds that generate acidic radicals by the radiation of actinic light rays or radioactive rays used for microresist and the like, and mixtures thereof.

The photo acid-generating agent is not particularly limited, and can be appropriately selected depending on the purpose. Examples thereof include triazines having at least one di- or tri-halomethyl group, 1,3,4-oxadiazole, naphthoquinone-1,2-diazide-4-sulfonyl halide, diazonium salts, phosphonium salts, sulfonium salts, iodonium salts, imide sulfonate, oxime sulfonate, diazodisulfone, disulfone, o-nitrobenzyl sulfonate, and the like. Among the above, imide sulfonate, oxime sulfonate, and o-nitrobenzyl sulfonate, which are compounds that generate a sulfonic acid, are particularly preferable.

In addition, compounds having a group that generates an acidic radical by the radiation of actinic light rays or radioactive rays or a compound introduced into a major chain or a side chain of a resin, for example, compounds described in the specification of U.S. Pat. No. 3,849,137, the specification of German Patent No. 3914407, respective publications of JP-A No. S63-26653, JP-A No. S55-164824, JP-A No. S62-69263, JP-A No. S63-146038, JP-A No. S63-163452, JP-A No. S62-153853, JP-A No. S63-146029 and the like can be used.

Furthermore, compounds described in the respective specifications of U.S. Pat. No. 3,779,778, European Patent No. 126,712, and the like can also be used as the acid-generating agent.

Examples of the triazine-based compound include 2-(4-methoxyphenyl)-4,6-bis(trichloromethyl)-s-triazine, 2-(4-methoxynaphthyl)-4,6-bis(trichloromethyl)-s-triazine, 2-(4-ethoxynaphthyl)-4,6-bis(trichloromethyl)-s-triazine, 2-(4-ethoxycarbonyl naphthyl)-4,6-bis(trichloromethyl)-s-triazine, 2,4,6-tris(monochloromethyl)-s-triazine, 2,4,6-tris(dichloromethyl)-s-triazine, 2,4,6-tris(trichloromethyl)-s-triazine, 2-methyl-4,6-bis(trichloromethyl)-s-triazine, 2-n-propyl-4,6-bis(trichloromethyl)-s-triazine, 2-(α,α,β-trichloroethyl)-4,6-bis(trichloromethyl)-s-triazine, 2-phenyl-4,6-bis(trichloromethyl)-s-triazine, 2-(p-methoxyphenyl)-4,6-bis(trichloromethyl)-s-triazine, 2-(3,4-epoxy phenyl)-4,6-bis(trichloromethyl)-s-triazine, 2-(p-chlorophenyl)-4,6-bis(trichloromethyl)-s-triazine, 2-[1-(p-methoxyphenyl)-2,4-butadienyl]-4,6-bis(trichloromethyl)-s-triazine, 2-styryl-4,6-bis(trichloromethyl)-s-triazine, 2-(p-methoxystyryl)-4,6-bis(trichloromethyl)-s-triazine, 2-(p-i-propyloxystyryl)-4,6-bis(trichloromethyl)-s-triazine, 2-(p-tolyl)-4,6-bis(trichloromethyl)-s-triazine, 2-(4-methoxynaphthyl)-4,6-bis(trichloromethyl)-s-triazine, 2-phenylthio-4,6-bis(trichloromethyl methyl)-s-triazine, 2-benzylthio-4,6-bis(trichloromethyl)-s-triazine, 4-(o-bromo-p-N,N-bis(ethoxycarbonylamino)phenyl)-2,6-di(trichloromethyl)-s-triazine, 2,4,6-tris(dibromomethyl)-s-triazine, 2,4,6-tris(tribromomethyl)-s-triazine, 2-methyl-4,6-bis(tribromomethyl)-s-triazine, 2-methoxy-4,6-bis(tribromomethyl)-s-triazine, and the like. The triazine-based compound may be solely used, or two or more triazine-based compounds may be used in a combination.

In the invention, among the photo acid-generating agents (1), compounds that generate a sulfonic acid are preferable, and an oxim sulfonate compound illustrated below is particularly preferably from the viewpoint of a high sensitivity.

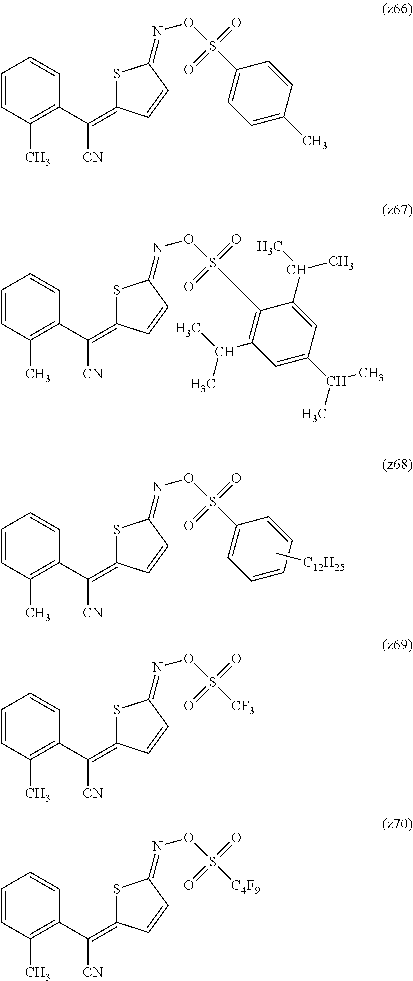

—Photo Radical-Generating Agent—

The photo radical-generating agent is a compound having a function of directly absorbing light or sensing light so as to cause a decomposition reaction or a hydrogen-extracting reaction, thereby generating radicals. The photo radical-generating agent preferably absorbs light in a wavelength range of from 300 nm to 500 nm.

A number of compounds are known as the photo radical-generating agent, and examples thereof include carbonyl compounds, ketal compounds, benzoin compounds, acridine compounds, organic peroxide compounds, azo compounds, coumarin compounds, azide compounds, metallocene compounds, hexaarylbiimidazole compounds, organic borate compounds, disulfone compounds, oxim ester compounds and acyl phosphine (oxide) compounds, all of which are described in JP-A No. 2008-268884. The photo radical-generating agent can be appropriately selected depending on the purpose. Among the above, benzophenone compounds, acetophenone compounds, hexaaryl biimidazole compounds, oxim ester compounds and acyl phosphine (oxide) compounds are particularly preferable from the viewpoint of exposure sensitivity.

Examples of the benzophenone compounds include benzophenone, Michler's ketone, 2-methylbenzophenone, 3-methylbenzophenone, N,N-diethylaminobenzophenone, 4-methylbenzophenone, 2-chlorobenzophenone, 4-bromobenzophenone, 2-carboxybenzophenone and the like. The benzophenone compound may be solely used, or two or more benzophenone compounds may be used in a combination.

Examples of the acetophenone compounds include 2,2-dimethoxy-2-phenyl acetophenone, 2,2-diethoxyacetophenone, 2-(dimethylamino)-2-[(4-methylphenyl)methyl]-1-[4-(4-morpholinyl)phenyl]-1-butanone, 1-hydroxycyclohexyl phenyl ketone, α-hydroxy-2-methylphenyl propanone, 1-hydroxy-1-methylethyl (p-isopropylphenyl) ketone, 1-hydroxy-1-methylethyl (p-dodecylphenyl) ketone, 2-methyl-1-(4-methylthiophenyl)-2-morpholinopropan-1-one, 1,1,1-trichloromethyl (p-butylphenyl) ketone, 2-benzyl-2-dimethyl amino-1-(4-morpholinophenyl)-butanone-1 and the like. Specific examples of commercially available products include IRGACURE 369 (registered trademark), IRGACURE 379 (registered trademark), IRGACURE 907 (registered trademark), all of which are manufactured by BASF Japan Ltd. The acetophenone compound may be solely used, or two or more acetophenone compounds may be used in a combination.

Examples of the hexaarylbiimidazole compounds include a variety of compounds described in the respective specifications of Japanese Patent Application Publication (JP-B) No. H6-29285, U.S. Pat. No. 3,479,185, U.S. Pat. No. 4,311,783, U.S. Pat. No. 4,622,286 and the like, and specific examples include 2,2′-bis(o-chlorophenyl)-4,4′,5,5′-tetraphenylbiimidazole, 2,2′-bis(o-bromophenyl)-4,4′,5,5′-tetraphenylbiimidazole, 2,2′-bis(o,p-dichlorophenyl)-4,4′,5,5′-tetraphenylbiimidazole, 2,2′-bis(o-chlorophenyl)-4,4′,5,5′-tetra(m-methoxyphenyl)biimidazole, 2,2′-bis(o,o′-dichlorophenyl)-4,4′,5,5′-tetraphenylbiimidazole, 2,2′-bis(o-nitrophenyl)-4,4′,5,5′-tetraphenylbiimidazole, 2,2′-bis(o-methylphenyl)-4,4′,5,5′-tetraphenylbiimidazole, 2,2′-bis(o-trifluorophenyl)-4,4′,5,5′-tetraphenylbiimidazole, and the like. The hexaarylbiimidazole compound may be solely used, or two or more hexaarylbiimidazole compounds may be used in a combination.

Examples of the oxim ester compounds include compounds described in J.C.S. Perkin II (1979) 1653-1660, J.C.S. Perkin II (1979) 156-162, Journal of Photopolymer Science and Technology (1995) 202 to 232, the respective specifications of JP-A No. 2000-66385, JP-A No. 2000-80068, Japanese Patent National Phase Publication No. 2004-534797 and the like. Specific examples of preferable oxim ester compounds include IRGACURE (registered trademark) OXE-01, IRGACURE (registered trademark) OXE-02, all of which are manufactured by BASF Japan Ltd., and the like. The oxim ester compound may be solely used, or two or more oxim ester compounds may be used in a combination.

Examples of the acylphosphine (oxide) compounds include IRGACURE (registered trademark) 819, DAROCUR (registered trademark) 4265, DAROCUR (registered trademark) TPO, all of which are manufactured by BASF Japan Ltd., and the like.

The photo radical-generating agent is particularly preferably 2-(dimethylamino)-2-[(4-methylphenyl)methyl]-1-[4-(4-morpholinyl)phenyl]-1-butanone, 2-benzyl-2-dimethylamino-1-(4-morpholinophenyl)-butanone-1,2-methyl-1-(4-methylthiophenyl)-2-morpholinopropan-1-one, 2,2′-bis(2-chlorophenyl)-4,4′,5,5′-tetraphenylbiimidazole, N,N-diethylaminobenzophenone, or 1-[4-(phenylthio)phenyl]-1,2-octanedione-2-(O-benzoyl oxime) from the viewpoint of exposure sensitivity and transparency.

The photopolymerization initiator of the component (b) may be solely used, or two or more photopolymerization initiators may be used in a combination. The content of the photopolymerization initiator in the conductive layer is preferably from 0.1% by mass to 50% by mass, more preferably from 0.5% by mass to 30% by mass, and still more preferably from 1% by mass to 20% by mass with respect to the total mass of the solid content of the photopolymerizable composition including the metallic nanowires. In a case in which a pattern including a conductive area and a non-conductive area, which will be described below, is formed in the conductive layer in the above numeric range, a favorable sensitivity and a pattern formability may be obtained.

[(c) Binder]

The binder can be appropriately selected from alkali soluble resins which are linear organic macromolecular polymers and have at least one group that accelerates alkali solubility (for example, a carboxylic group, a phosphoric acid group, a sulfonic acid group, or the like) in molecules (preferably molecules including acrylic copolymers and styrene-based copolymers as the main chains).

Among the above, alkali soluble resins that are soluble in organic solvent and in alkali aqueous solutions are preferable, and alkali soluble resins that have an acid dissociable group and become soluble in alkali when the acid dissociable group is dissociated due to the action of an acid are particularly preferable.

Here, the acid dissociable group refers to a functional group that can be dissociated in the presence of an acid.

In the production of the binder, for example, a method for which a well-known radical polymerization method is used can be applied. Polymerization conditions such as the temperature and pressure when an alkali soluble resin is produced using the radical polymerization method, the kind and amount of the radical initiator, and the kind of the solvent can be easily set by a person skilled in the art, and the conditions can be experimentally specified.

The linear organic macromolecular polymer is preferably a polymer having a carboxylic acid at a side chain.

Examples of the polymer having a carboxylic acid at a side chain include mathacrylic acid copolymers, acrylic acid copolymers, itaconic acid copolymers, crotonic acid copolymers, maleic acid copolymers, partially esterified maleic acid copolymers, and the like as described in the respective publications of JP-A No. S59-44615, JP-B No. S54-34327, JP-B No. 558-12577, JP-B No. S54-25957, JP-A No. S59-53836 and JP-A No. S59-71048, acidic cellulose derivatives having a carboxylic acid at a side chain, polymers obtained by adding an acid anhydride to a polymer having a hydroxy group, and, furthermore, macromolecular polymers having a (meth)acryloyl group at a side chain can also be included in preferable examples thereof.

Among the above, benzyl (meth)acrylate/(meth)acrylic acid copolymers and multi-component copolymers made of benzyl (meth)acrylate/(meth)acrylic acid/other monomers are particularly preferable.

Furthermore, macromolecular polymers having a (meth)acryloyl group at a side chain or multi-component copolymers made of (meth)acrylic acid/glycidyl (meth)acrylate/other monomers are also included in useful examples thereof. The polymers can be mixed in at an arbitrary amount and used.

In addition to the above, 2-hydroxypropyl (meth)acrylate/polystyrene macromonomer/benzyl methacrylate/methacrylic acid copolymer, 2-hydroxy-3-phenoxypropyl acrylate/polymethyl methacrylate macromonomer/benzyl methacrylate/methacrylic acid copolymer, 2-hydroxyethyl methacrylate/polystyrene macromonomer/methyl methacrylate/methacrylic acid copolymer, 2-hydroxyethyl methacrylate/polystyrene macromonomer/benzyl methacrylate/methacrylic acid copolymer, all of which are described in the publication of JP-A No. H7-140654, and the like are included in the useful examples.

Specific constituent unit of the alkali soluble resin is preferably a (meth)acrylic acid and other monomers that can be copolymerized with the (meth)acrylic acid.

Examples of the monomers that can be copolymerized with the (meth)acrylic acid include alkyl (meth)acrylates, aryl (meth)acrylates, vinyl compounds, and the like. In the monomers, the hydrogen atoms in the alkyl and aryl groups may be substituted by a substituent.

Examples of the alkyl (meth)acrylates or the aryl (meth)acrylates include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, cyclohexyl (meth)acrylate, dicyclopentanyl (meth)acrylate, dicyclopentenyl (meth)acrylate, dicyclopentenyloxyethyl (meth)acrylate, glycidyl methacrylate, tetrahydrofurfuryl methacrylate, polymethyl methacrylate macromonomer, and the like. The alkyl (meth)acrylate or the aryl (meth)acrylate may be solely used, or two or more may be used in a combination.

Examples of the vinyl compounds include styrene, a-methyl styrene, vinyl toluene, acrylonitrile, vinyl acetate, N-vinyl pyrrolidone, polystyrene macromonomers, CH₂═CR¹¹R¹² [here, R¹¹ represents a hydrogen atom or an alkyl group having 1 to 5 carbon atoms, and R¹² represents an aromatic hydrocarbon ring having 6 to 10 carbon atoms], and the like. The vinyl compound may be solely used, or two or more vinyl compounds may be used in a combination.

The weight average molecular weight of the binder is preferably from 1,000 to 500,000, more preferably from 3,000 to 300,000, and still more preferably from 5,000 to 200,000 from viewpoints of alkali dissolution rate, film properties and the like.

Here, the weight average molecular weight is measured using gel permeation chromatography, and can be obtained using the standard polystyrene calibration curve.

A content of the binder of the component (c) in the conductive layer is preferably from 5% by mass to 90% by mass, more preferably from 10% by mass to 85% by mass, and still more preferably from 20% by mass to 80% by mass with respect to the total mass of the solid content of the photopolymerizable composition which includes the metallic nanowires. When the content is in the preferable range, both developability and the conduction of the metallic nanowires can be satisfied.

[(d) Additives Other than the Components (a) to (c)]

Examples of additives other than the components (a) to (c) include a variety of additives such as a chain-transfer agent, a crosslinking agent, a dispersant, a solvent, a surfactant, an antioxidant, a sulfuration inhibitor, a metal corrosion inhibitor, a viscosity adjuster, a preservative and the like.

(d-1) Chain Transfer Agent

The chain-transfer agent is used to improve the exposure sensibility of the photopolymerizable composition. Examples of the chain transfer agent include N,N-dialkylamino benzoic acid alkyl ester such as N,N-dimethylaminobenzoic acid ethyl ester; mercapto compounds having a heterocyclic ring such as 2-mercaptobenzothiazole, 2-mercaptobenzoxazole, 2-mercaptobenzimidazole, N-phenyl-mercaptobenzimidazole and 1,3,5-tris(3-mercaptobutyloxyethyl)-1,3,5-triazine-2,4,6(1H,3H,5H)-trione; aliphatic polyfuncational mercapto compounds such as pentaerythritol tetrakis(3-mercaptopropionate), pentaerythritol tetrakis(3-mercaptobutylate) and 1,4-bis(3-mercaptobutyloxy)butane; and the like. The chain transfer agent may be solely used, or two or more chain transfer agents may be used in a combination.

A content of the chain transfer agent in the conductive layer is preferably 0.01% by mass to 15% by mass, more preferably 0.1% by mass to 10% by mass, and still more preferably 0.5% by mass to 5% by mass with respect to the total mass of the solid content of the photopolymerizable composition which includes the metallic nanowires.

(d-2) Crosslinking Agent

The crosslinking agent is a compound that forms a chemical bond using a free radical or an acid and heat and cures the conductive layer. Examples thereof include melamine-based compounds, guanamine-based compounds, glycol uryl-based compounds, urea-based compounds, phenol-based compounds, ether compounds of phenol, which are substituted by at least one group selected from methylol groups, alkoxy methyl groups and acyloxy methyl groups, epoxy-based compounds, oxetane-based compounds, thioepoxy-based compounds, isocyanate-based compounds, azide-based compounds, compounds having an ethylenically unsaturated group including a methacryloyl group, an acryloyl group or the like, and the like. Among the above, epoxy-based compounds, oxetane-based compounds and compounds having an ethylenically unsaturated group are particularly preferable from viewpoints of film properties, heat resistance and solvent resistance.

In addition, the oxetane-based compound can be solely used, or can be used as a mixture with the epoxy-based compound. Particularly, a case in which the oxetane-based compound is used in a combination with the epoxy-based compound is preferable since the reactivity is high, and film properties improve.

Meanwhile, in a case in which the compound having an ethylenically unsaturated double-bonded group is used as the crosslinking agent, the crosslinking agent is also included in examples of the polymerizable compound (c), and thus the content thereof is also supposed to be included in the content of the polymerizable compound (c) in the invention.

The content of the crosslinking agent in the conductive layer is preferably from 1% by mass to 250% by mass, and more preferably from 3% by mass to 200% by mass with respect to the total mass of the solid content of the photopolymerizable composition including the metallic nanowires.

(d-3) Dispersant

The dispersant is used in order to prevent the agglomeration of the metallic nanowires and to disperse the metallic nanowires in the photopolymerizable composition. The dispersant is not particularly limited as long as the dispersant can disperse the metallic nanowires, and can be appropriately selected depending on the purpose. For example, a commercially available dispersant can be used as a pigment dispersant, and a macromolecular dispersant having a property of being adsorbed to the metallic nanowires is particularly preferable. Examples of the macromolecular dispersant include polyvinyl pyrrolidones, BYK series (registered trademark; manufactured by BYK JAPAN K.K.), SOLSPERSE series (registered trademark; manufactured by the LUBRIZOL Corporation), AJISPER series (registered trademark; manufactured by AJINOMOTO Co., Inc.) and the like.

Meanwhile, in a case in which the macromolecular dispersant is further added separately as the dispersant in addition to the macromolecular dispersant used for the production of the metallic nanowires, the macromolecular dispersant is also included in examples of the binder of the component (c), and thus the content thereof is also supposed to be included in the content of the component (c).

A content of the dispersant in the conductive layer is preferably from 0.1 parts by mass to 50 parts by mass, more preferably from 0.5 parts by mass to 40 parts by mass, and particularly preferably from 1 part by mass to 30 parts by mass with respect to 100 parts by mass of the binder of the component (c).

When the content of the dispersant is 0.1 parts by mass or more, the agglomeration of the metallic nanowires in the dispersion liquid is effectively suppressed, and, when the content is 50 parts by mass or less, stable liquid coats are formed in a coating step, and the occurrence of applying unevenness is suppressed, which is preferable.

(d-4) Solvent

The solvent is a component used to form the composition including (i) the metallic nanowires, (ii) the tetraalkoxy compound and the organo alkoxy compound, and the photopolymerizable composition into a coating liquid for a film shape on the surface of the base material, and can be appropriately selected depending on the purpose. Examples thereof include propylene glycol monomethyl ether, propylene glycol monomethyl ether acetate, ethyl 3-methoxypropionate, methyl 3-ethoxypropionate, ethyl lactate, 3-methoxybutanol, water, 1-methoxy-2-propanol, isopropyl acetate, methyl lactate, N-methylpyrrolidone (NMP), γ-butyrolactone (GBL), propylene carbonate and the like. The solvent may be solely used, or two or more solvents may be used in a combination.

A concentration of the solid content of the coating liquid including the solvent is preferably in a range of from 0.1% by mass to 20% by mass.

(d-5) Metal Corrosion Inhibitor

The conductive layer preferably contains a metal corrosion inhibitor of the metallic nanowires. The metal corrosion inhibitor is not particularly limited, and can be appropriately selected depending on the purpose. Preferable examples thereof include thiols, azoles and the like.

When the photopolymerizable composition contains the metal corrosion inhibitor, a superior antirust effect can be exhibited. The metal corrosion inhibitor can be supplied to compositions for forming photosensitive layers by being added in a state of being dissolved in an appropriate solvent or in a powder form, or by preparation a conductive film using a coating liquid for the conductive layer, which will be described below, and then immersing the conductive film in a metal corrosion inhibitor bath.

In a case in which the metal corrosion inhibitor is added, the metal corrosion inhibitor is preferably contained in from 0.5% by mass to 10% by mass with respect to the metallic nanowires.

Additionally, for the matrix, the macromolecular compound used as the dispersant when producing the metallic nanowires can be used as at least a part of components that form the matrix.

<<Intermediate Layer>>

At least one intermediate layer is preferably provided between the base material and the conductive layer. When the intermediate layer is provided between the base material and the conductive layer, it becomes possible to improve at least one of adhesion between the base material and the conductive layer, the light transmittance of the conductive layer, the haze of the conductive layer, and the film strength of the conductive layer.

Examples of the intermediate layer include an adhesive layer for improving the adhesive force between the base material and the conductive layer, a functional layer that improves functionality derived from interactions with the components included in the conductive layer, and the like, and any of the intermediate layers are appropriately provided depending on the purpose.

The configuration of the conductive member that further includes the intermediate layer will be described with reference to the drawings.

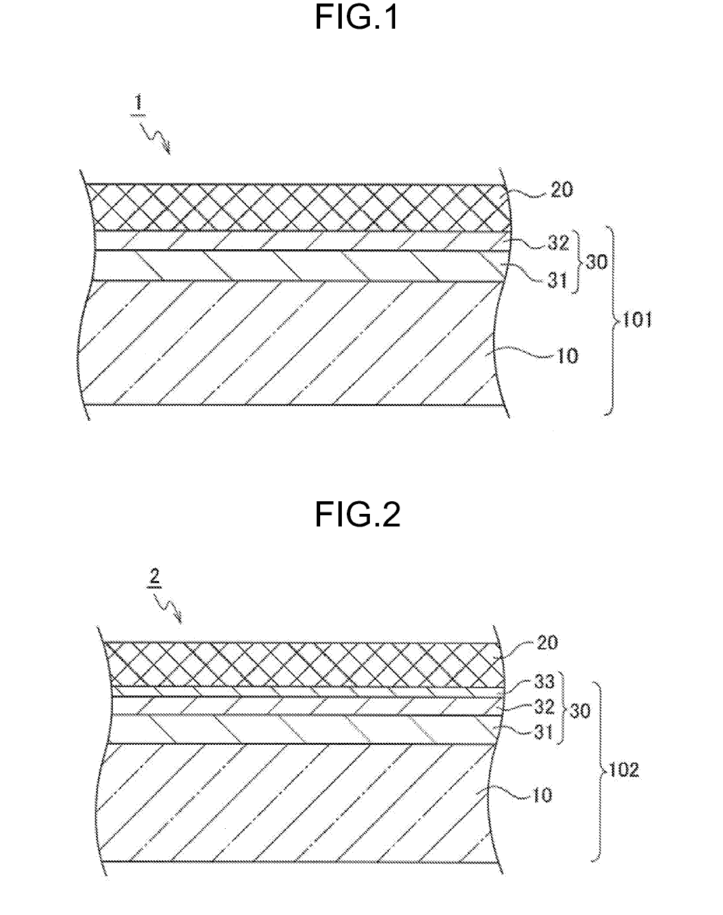

FIG. 1 is a schematic cross-sectional view illustrating a conductive member 1 that is a first exemplary aspect of the conductive member according to the first embodiment. In the conductive member 1, a conductive layer 20 is provided on a substrate 101 formed by including an intermediate layer on a base material. An intermediate layer 30 including a first adhesion layer 31 having an excellent affinity to the base material 10 and a second adhesion layer 32 having an excellent affinity to the conductive layer 20 is provided between the base material 10 and the conductive layer 20.

FIG. 2 is a schematic cross-sectional view illustrating a conductive member 2 that is a second exemplary aspect of the conductive member according to the first embodiment. In the conductive member 2, the conductive layer 20 is provided on a substrate 102 formed by including an intermediate layer on a base material. The intermediate layer 30 including a functional layer 33 adjacent to the conductive layer 20 in addition to the same first adhesion layer 31 and the same second adhesion layer 32 as in the first embodiment is provided between the base material 10 and the conductive layer 20.

The material used for the intermediate layer 30 is not particularly limited as long as the material improves at least any one of the above characteristics.

For example, in a case in which the conductive member includes an adhesion layer as the intermediate layer, the adhesion layer includes a material selected from a polymer used as an adhesive, a silane coupling agent, a titanium coupling agent, a sol-gel film obtained by hydrolyzing and polycondensing a Si alkoxide compound, and the like.

The intermediate layer (that is, the intermediate layer in a case in which the intermediate layer 30 is a single layer, and the sub-intermediate layer in contact with the conductive layer in a case in which the intermediate layer 30 includes plural sub-intermediate layers) in contact with the conductive layer is preferably the functional layer 33 including a compound having a functional group (hereinafter, referred to as “interactable functional group”) that can electrostatically interact with metallic nanowires in the conductive layer 20 since a conductive layer that is excellent in terms of the light transmittance, haze and film strength can be obtained. In a case in which the conductive member includes the above intermediate layer, a conductive layer that is excellent in terms of film strength can be obtained even when the conductive layer 20 includes the metallic nanowires and organic macromolecules.

The working mechanism thereof is not clearly understood, but it is considered that, when the intermediate layer including a compound having a functional group that can interact with the metallic nanowires in the conductive layer 20 is provided, the interaction between the metallic nanowires in the conductive layer and the compound having the functional group in the intermediate layer suppresses the agglomeration of a conductive material in the conductive layer, thereby improves the uniform dispersibility, suppresses the degradation of transparency or haze caused by the agglomeration of the conductive material in the conductive layer, and improves the film strength due to the adhesiveness. The intermediate layer that can develop the interaction will be sometimes called a functional layer. Since the functional layer develops the effects due to the interaction with the metallic nanowires, the effects are developed without depending on the matrix included in the conductive layer as long as the conductive layer includes the metallic nanowires.

The functional group including functional groups that can interact with the metallic nanowires is preferably, in a case in which the metallic nanowires are silver nanowires, at least one selected from a group consisting of amido groups, amino groups, mercapto groups, carboxylic acid groups, sulfonic acid groups, phosphoric acid groups, phosphonic acid groups and salts thereof, and the compound having the functional group preferably includes one or more functional group(s) selected from the group consisting functional groups thereof. Among them, the functional group is more preferably an amino group, a mercapto group, a phosphoric acid group, a phosphonic acid group or a salt thereof, and even more preferably an amino group.

Examples of the compound having the functional group include compounds having an amide group such as ureidopropyl triethoxysilane, polyacrylamide and polymethacrylamide; compounds having an amino group such as N-β(aminoethyl)γ-aminopropyl trimethoxysilane, 3-aminopropyl triethoxysilane, bis(hexamethylene)triamine, N,N′-bis(3-aminopropyl)-1,4-butylenediamine tetrahydrochloride, spermine, diethylene triamine, m-xylenediamine and methaphenylene diamine; compounds having a mercapto group such as 3-mercapto propyl trimethoxysilane, 2-mercaptobenzothiazole and toluene-3,4-dithiol; compounds having a group of a sulfonic acid or a salt thereof such as poly(sodium p-styrene sulfonate) and poly(2-acrylamide-2-methylpropane sulfonate); compounds having a carboxylic acid group such as polyacrylic acid, polymethacrylic acid, polyasparatic acid, terephthalic acid, cinnamic acid, fumaric acid and succinic acid; compounds having a phosphoric acid group such as PHOSMER PE, PHOSMER CL, PHOSMER M, PHOSMER MH (trade names, manufactured by UNI CHEMICALS & Co), polymers thereof, POLYPHOSMER M-101, POLYPHOSMER PE-201 and POLYPHOSMER MH-301 (trade names, manufactured by DAP Co., Ltd.); and compounds having a phosphonic acid group such as phenyl phosphonic acid, decylphosphonic acid, methylene diphosphonic acid, vinyl phosphonic acid and allyl phosphonic acid.

When the above functional group is selected, the interaction between the metallic nanowires and the functional group in the intermediate layer is caused after the application of the coating liquid for forming conductive layers, and the agglomeration of the metallic nanowires during drying is suppressed, whereby a conductive layer in which the metallic nanowires are uniformly dispersed can be formed.

The intermediate layer can be formed by applying and drying a liquid in which a compound that configures the intermediate layer is dissolved and dispersed (suspended or emulsified) on the base material. As the applying method, an ordinarily-used method can be used. The applying method is not particularly limited, and can be appropriately selected depending on the purpose. Examples thereof include a roll coating method, a bar coating method, a dip coating method, a spin coating method, a casting method, a die coating method, a blade coating method, a gravure coating method, a curtain coating method, a spray coating method, a doctor coating method, and the like.

The water droplet contact angle on a surface (intermediate layer surface) of the intermediate layer on the opposite side to the surface facing the base material is preferably from 3° to 50°, more preferably from 5° to 40°, still more preferably from 5° to 35°, and most preferably from 5° to 30°. When the water droplet contact angle on the intermediate layer surface is in the above range, a conductive layer in which defects such as unevenness are further suppressed can be formed. This can be considered to be because the liquid composition for forming conductive layers is well soaked and spread when being supplied. In addition, since the surface is activated, the adhesiveness with the conductive layer tends to be improved.

The water droplet contact angle on the intermediate layer surface is measured at 25° C. using a contact angle meter.

The conductive member has excellent abrasion resistance. The abrasion resistance can be evaluated using the following method (1) or (2).

(1) When a abrasion resistance test in which a surface of the conductive layer is reciprocally rubbed 50 reciprocations with a pressure of 125 g/cm² using a continuous loading scratching intensity tester (for example, a continuous loading scratching intensity tester type 18s manufactured by SHINTO SCIENTIFIC Co., Ltd.) and a gauze piece (for example, FC gauze; trade name, manufactured by HAKUJUJI Co., Ltd.) is carried out, the ratio of the surface resistivity (Ω/□) of the conductive layer after the abrasion resistance test to the surface resistivity (Ω/□) of the conductive layer before the abrasion resistance test is 100 or less.

In a case in which a conductive layer of the related art in which the metallic nanowires are used is used in a low-resistance area (0.1Ω/□ to 1000Ω/□), since a small amount of the matrix is used in order to increase the number of the contact points between the metallic nanowires, the film strength is extremely weak. Therefore, the conductive layer is damaged and the metallic nanowires are cut while the conductive layer is handled to manufacture touch panels and the like. This is the kind of improvement that has been required in order to employ a conductive layer in which the metallic nanowires are used in products. Since the conductive member that is an embodiment of the invention has excellent abrasion resistance as described above, the occurrence of the above malfunction when handling the conductive layer can be reduced so that the conductive member becomes suitable for long-term use as an electrode in touch panels.

(2) When a bending test is carried out on the conductive member 20 times using a cylindrical mandrel bending tester (for example, a bending test manufactured by Cotec Corporation) having a cylindrical mandrel with a diameter of 10 mm, the ratio of the surface resistivity (Ω/□) of the conductive layer after the abrasion resistance test to the surface resistivity (Ω/□) of the conductive layer before the abrasion resistance test is 2.0 or less.

A conductive member of the related art in which the metallic nanowires are used did not have sufficient bending resistance to be used for 3D touch panel displays or spherical displays. In contrast to the conductive member of the related art, since the conductive member that is an embodiment of the invention has excellent bending resistance as described above, the conductive member is suitable for three-dimensional processing, and thus can be used for an electrode in 3D touch panel displays or spherical displays.

The conductive member exhibits specific effects that conduction, transparency, abrasion resistance, heat resistance, heat and moisture resistance, and bending resistance are excellent when the conductive layer contains (i) the metallic nanowires having an average short-axis length of 150 nm or less and (ii) the cured sol-gel substance obtained by hydrolyzing and polycondensing the tetraalkoxy compound represented by Formula (I) and the organoalkoxy compound represented by Formula (II).

The reason is not evident, but it is assumed that the specific effects have a close relationship with the conductive layer including the cured sol-gel substance obtained by hydrolyzing and polycondensing the tetraalkoxy compound and the organoalkoxy compound. For example, in a case in which silver nanowires are used as the metallic nanowires, it is assumed that, while a polymer having a hydrophilic group, which is used as a dispersant when preparing the silver nanowires, hinders the contact between the silver nanowires at least to some extent, in the conductive member according to the invention, the dispersant that covers the silver nanowires is detached in the forming process of the cured sol-gel substance, and, furthermore, when the specific alkoxide compound is polycondensed, a polymer layer that covers the surfaces of the silver nanowires consequently condenses, and therefore the number of the contact points between many silver nanowires increases so that, consequently, a conductive member with a low surface resistivity is obtained. Furthermore, the conductive layer including the cured sol-gel substance obtained by hydrolyzing and polycondensing only the tetraalkoxy compound has an excessively high crosslinking density and forms a brittle film such as glass so that there is a possibility that cracking occurs when the conductive layer is bent and thus conduction wires are cut. In contrast to what has been described above, in the conductive layer including the cured sol-gel substance obtained by hydrolyzing and polycondensing the tetraalkoxy compound and the organoalkoxy compound, it is assumed that the crosslinking density is adjusted in an appropriate range, and therefore the conductive layer has excellent film strength, excellent abrasion resistance and appropriate flexibility, and, consequently, the conductive layer is superior in terms of bending resistance. In addition, since the conductive layer allows the transmission of substances such as oxygen, ozone and moisture in a well-balanced range, the conductive layer is assumed to be also excellent in terms of heat resistance and moisture and heat resistance. As a result, in a case in which the conductive member is used in, for example, a touch panel, the occurrence of a malfunction can be reduced while handling the conductive member, and the yield can be improved so that the conductive member can be freely bent, and the aptitude for the conductive member to be three-dimensionally processed into 3D touch panel displays, spherical displays, and the like can be supplied.

Since the conductive layer has high conduction, high transparency and high film strength, and is excellent in terms of abrasion resistance and bendability, the conductive member is widely applied to touch panels, display electrodes, electromagnetic wave shields, organic EL display electrodes, inorganic EL display electrodes, electronic paper, flexible display electrodes, integrated solar cells, liquid crystal displays, touch panel function-embedded display apparatuses, and a variety of other devices. Among the above, the conductive member is particularly preferably applied to touch panels and solar cells.

<<Touch Panel>>

The conductive member is applied to, for example, surface capacitive-type touch panels, projected capacitive-type touch panels, resistive-type touch panels and the like. Here, examples of the touch panel include so-called touch sensors and touch pads.

A layer configuration of the touch panel sensor electrode portion in the touch panel is preferably any of an attachment method in which two transparent electrodes are attached, a method in which transparent electrodes are provided on both surfaces of a base material, a single surface jumper or through hole method, and a single surface lamination method.

The surface capacitive-type touch panels are described in, for example, Japanese Patent National Phase Publication No. 2007-533044.

<<Solar Cell>>

The conductive member is useful as a transparent electrode in integrated solar cells (hereinafter, also referred to as solar cell devices).

The integrated solar cell is not particularly limited, and solar cells that are generally used as solar cell devices can be used. Examples thereof include single crystalline silicon-based solar cell devices, polycrystalline silicon-based solar cell devices, amorphous silicon-based solar cell devices configured in a single junction, tandem structure or the like, semiconductor solar cell devices of Group III-V compounds such as gallium arsenide (GaAs) or indium phosphide (InP), semiconductor solar cell devices of Group II-VI compounds such as cadmium telluride (CdTe), semiconductor solar cell devices of Group I-III-VI compounds such as copper/indium/selenium-based compounds (so-called CIS-based compounds), copper/indium/gallium/selenium-based compounds (so-called CIGS-based compounds) and copper/indium/gallium/selenium/sulfur-based compounds (so-called CIGSS-based compounds), dye-sensitized solar cell devices, organic solar cell devices, and the like. Among the above, the solar cell device is preferably an amorphous silicon-based solar cell device configured in a tandem structure or the like, or a semiconductor solar cell device of Group I-III-VI compounds such as copper/indium/selenium-based compounds (so-called CIS-based compounds), copper/indium/gallium/selenium-based compounds (so-called CIGS-based compounds) and copper/indium/gallium/selenium/sulfur-based compounds (so-called CIGSS-based compounds).

In the case of the amorphous silicon-based solar cell configured in a tandem structure or the like, amorphous silicon, a fine crystalline silicon thin film layer, a thin film including Ge in amorphous silicon or a fine crystalline silicon thin film layer, or, furthermore, two or more layers of the above in a tandem structure is used as a photoelectric conversion layer. Films thereof are formed using plasma CVD or the like.

The conductive member can be applied to all of the above solar cell devices. The conductive member may be included in any portion of the solar cell device, but is preferably included so that the conductive layer is disposed adjacent to the photoelectric conversion layer. The positional relationship with the photoelectric conversion layer is preferably one of the following configurations, but is not limited thereto. In addition, the following configurations do not describe all portions of the solar cell device, and describe portions as simply as the positional relationship of the transparent conductive layer can be clear. Here, configurations included in parenthesis correspond to the conductive member.

(A) [base material-conductive layer]-photoelectric conversion layer

(B) [base material-conductive layer]-photoelectric conversion layer-[conductive layer-base material]

(C) substrate-electrode-photoelectric conversion layer-[conductive layer-base material]

(D) rear surface electrode-photoelectric conversion layer-[conductive layer-base material]

The details of the above solar cell are described in, for example, JP-A No. 2010-87105.

### EXAMPLES

Hereinafter, examples of the invention will be described, but the invention is not limited to the examples. Meanwhile, “%” and “parts” in the examples, which indicate content rates, are all by mass.

In the following examples, the average short axis length (average diameter) and average long axis length of metallic nanowires, the coefficient of variation of the short axis length, and the proportion of silver nanowires having an aspect ratio of 10 or more were measured in the following manners.

<The Average Short Axis Length (Average Diameter) and Average Long Axis Length of Metallic Nanowires>

The short axis lengths (diameters) and long axis lengths of 300 metallic nanowires randomly selected from metallic nanowires magnified using a transmission electron microscope (TEM, JEM-2000FX; trade name, manufactured by JELO Ltd.) were measured, and the average short axis length (diameter average) and average long axis length of the metallic nanowires was obtained from the average values.

<The Coefficient of Variation of the Short Axis Length (Diameter) of the Metallic Nanowires>

The short axis lengths (diameters) of 300 nanowires randomly selected from the transmission electron microscopic (TEM) image were measured, and a standard deviation and an average value of the 300 nanowires were computed, thereby obtaining the coefficient of variation.

<The Proportion of Silver Nanowires Having an Aspect Ratio of 10 or More>

The short axis lengths of 300 silver nanowires were observed using a transmission electron microscope (JEM-2000FX described above), the amount of silver that had penetrated filtration paper was measured, and silver nanowires having a short axis length of 50 nm or less and a long axis length of 5 μm or more were obtained as the proportion (%) of silver nanowires having an aspect ratio of 10 or more.

Meanwhile, when the ratio of the silver nanowires was obtained, the silver nanowires were separated using a membrane filter (FALP 02500; trade name, manufactured by NIHON MILLIPORE K.K., pore diameter of 1.0 μm).

### Preparation Example 1

### The Preparation of a Silver Nanowire Aqueous Dispersion Liquid (1)

The following addition liquids A, G and H were prepared in advance.

[Addition Liquid A]

Silver nitrate powder (0.51 g) was dissolved in pure water (50 mL). After that, 1N ammonia water was added until the solution became transparent. In addition, pure water was added so that the total amount became 100 mL.

[Addition Liquid G]

Glucose powder (0.5 g) was dissolved in pure water (140 mL), thereby preparing an addition liquid G.

[Addition Liquid H]

Hexadecyltrimethylammonium bromide (HTAB) powder (0.5 g) was dissolved in pure water (27.5 mL), thereby preparing an addition liquid H.

Next, a silver nanowire aqueous dispersion liquid (1) was prepared in the following manner.

Pure water (410 mL) was put into a three-neck flask, and the addition liquid H (82.5 mL) and the addition liquid G (206 mL) were added while being stirred at 20° C. (first step). The addition liquid A (206 mL) was added to the above solution at a flow rate of 2.0 mL/min and a stirring rate of 800 rpm (second step). After 10 minutes, the addition liquid H (82.5 mL) was added (third step). After that, the solution was heated at 3° C./minute until the inner temperature reached 73° C. After that, the stirring rate was reduced to 200 rpm, and the solution was heated for 5.5 hours.

After the obtained aqueous dispersion liquid was cooled, an ultrafiltration module SIP1013 (trade name, manufactured by ASAHI KASEI Corporation, cutoff molecular weight: 6,000), a magnetic pump and a stainless steel cup were connected using silicone tubes, thereby preparing an ultrafiltration apparatus.

The silver nanowire aqueous dispersion liquid (aqueous solution) was put into the stainless steel cup, and ultrafiltration was carried out by operating the pump. When a filtration from the module reached 50 mL, distilled water (950 mL) was added to the stainless steel cup, and the stainless steel cup was washed. After the washing was repeated until the conductivity became 50 μS/cm or less, condensation was carried out, thereby obtaining a 0.84% by mass silver nanowire aqueous dispersion liquid.

For the obtained silver nanowires of Preparation Example 1, the average short axis length, the average long axis length, the proportion of silver nanowires having an aspect ratio of 10 or more, and the coefficient of variation of the short axis lengths of the silver nanowires were measured.

As a result, silver nanowires having an average short axis length of 17.2 nm, an average long axis length of 34.2 μm, and a coefficient of variation of 17.8% were obtained. In the obtained silver nanowires, the proportion of silver nanowires having an aspect ratio of 10 or more was 81.8%. Hereinafter, the “silver nanowire aqueous dispersion liquid (1)” indicates the silver nanowire aqueous dispersion liquid obtained using the above method.

### Preparation Example 2

### Pretreatment of a Glass Substrate

First, a 0.7 mm-thick alkali-free glass substrate that had been immersed in a 1% sodium hydroxide aqueous solution was irradiated with ultrasonic waves for 30 minutes using an ultrasonic washer, subsequently, washed using ion exchanged water for 60 seconds, and then subjected to a heating treatment at 200° C. for 60 minutes. After that, a silane coupling liquid (N-β-(aminoethyl)-γ-aminopropyl trimethoxysilane 0.3% aqueous solution, trade name: KBM603; trade name, manufactured by SHIN-ETSU CHEMICAL Co., Ltd.) was showered for 20 seconds, and pure water shower washing was carried out. Hereinafter, the “glass substrate” indicates an alkali-free glass substrate obtained using the pretreatment.

### Preparation Example 3

### Pretreatment of a PET Substrate

An adhesion solution 1 was prepared in the following composition.

[Adhesion solution 1]

| | |
|---|---|
| TAKELAC WS-4000 | 5.0 parts |
| (trade name, manufactured by MITSUI CHEMICALS, Inc., solid content | |
| concentration 30%) | |
| Surfactant | 0.3 parts |
| (NALOACTY HN-100; trade name, manufactured by SANYO CHEMICALS | |
| INDUSTRIES, Ltd.) | |
| Surfactant | 0.3 parts |
| (SUNDET BL; trade name, manufactured by MITSUI CHEMICALS, Inc., solid | |
| content concentration 43%,) | |
| Water | 94.4 parts |

A corona discharge treatment was carried out on one surface of a 125 μm-thick PET film 10. The adhesion solution was coated on the corona discharge-treated surface, and dried at 120° C. for 2 minutes, thereby forming a 0.11 μm-thick first adhesion layer 31.

An adhesion solution 2 was prepared in the following composition.

[Adhesion solution 2]

| | |
|---|---|
| Tetraethoxysilane | 5.0 parts |
| (KBE-04; trade name, manufactured by SHIN-ETSU CHEMICAL Co., Ltd.) | |
| 3-Glycidoxypropyltrimethoxysilane | 3.2 parts |
| (KBM-403; trade name, manufactured by SHIN-ETSU CHEMICAL Co., Ltd.) | |
| 2-(3,4-epoxycyclohexyl)ethyltrimethoxysilane | 1.8 parts |
| (KBM-303; trade name, manufactured by SHIN-ETSU CHEMICAL Co., Ltd.) | |
| Aqueous solution of acetic acid (acetic acid concentration = 0.05%, pH = 5.2) | 10.0 parts |
| Curing agent | 0.8 parts |
| (boric acid, manufactured by Wako Pure Chemical Industries) | |
| Colloidal silica | 60.0 parts |
| (SNOWTEX O; trade name, manufactured by NISSAN CHEMICALS | |
| INDUSTRIES, Ltd., average particle diameter 10 nm to 20 nm, solid content concentration | |
| 20%, pH = 2.6) | |
| Surfactant | 0.2 parts |
| (NALOACTY HN-100 described above) | |
| Surfactant | 0.2 parts |
| (SUNDET BL; trade name, manufactured by MITSUI CHEMICALS, Inc., solid | |
| content concentration 43%) | |

The adhesion solution 2 was prepared using the following method. 3-Glycidoxypropyl trimethoxysilane was added dropwise over 3 minutes to the aqueous solution of acetic acid while violently stirring the aqueous solution of acetic acid. Next, 2-(3,4-epoxycyclohexyl)ethyl trimethoxysilane was added over 3 minutes while strongly stirring the aqueous solution of acetic acid. Next, tetraethoxysilane was added over 5 minutes while strongly stirring the aqueous solution of acetic acid, and then the solution was stirred for 2 hours. Next, the colloidal silica, the curing agent and the surfactants were sequentially added, thereby preparing the adhesion solution 2.

After the surface of the first adhesion layer 31 was subjected to the corona discharge treatment, the adhesion solution 2 was applied to the surface using a bar coating method, heated and dried at 170° C. for 1 minute so as to form a 0.5 μm-thick second adhesion layer 32, thereby obtaining a PET substrate 101 in the configuration illustrated in FIG. 1.

(Preparation of Conductive Member 1)

It was confirmed that a solution of an alkoxide compound having the following composition was stirred at 60° C. for 1 hour so as to become homogeneous. The obtained sol-gel solution (3.44 parts) and the silver nanowire aqueous dispersion liquid (1) obtained in Preparation Example 1 (16.56 parts) are mixed, and, furthermore, diluted using distilled water, thereby obtaining a sol-gel coating liquid. A corona discharge treatment was carried out on the surface of the second adhesion layer 32 in the PET substrate 101, the sol-gel coating liquid was applied to the surface using a bar coating method so that the amount of silver became 0.020 g/m² and the total application amount of the solid content became 0.150 g/m², then, dried at 175° C. for 1 minute so as to cause a sol-gel reaction, thereby forming a conductive layer 20. Thereby, a non-patterned conductive member 1 having the configuration illustrated in the cross-sectional view of FIG. 1 was obtained. The mass ratio of the total amount of tetraethoxysilane and 3-glycidoxypropyl trimethoxysilane to the silver nanowires in the conductive layer became 6.5/1.

<Solution of an alkoxide compound>

| | |
|---|---|
| Tetraethoxysilane | 2.5 parts |
| (KBE-04 (the same as described above)) | |
| 3-Glycidoxypropyltrimethoxysilane | 2.5 parts |
| (KBM-403 (the same as described above)) | |
| 1% aqueous solution of acetic acid | 10.0 parts |
| Distilled water | 4.0 parts |

In addition, the average film thickness of the conductive layer measured using a stylus type surface profiler (DEKTAK (registered trademark) 150, manufactured by Bruker AXS, Inc.) was 0.085 μm.

Furthermore, the average film thickness of the conductive layer measured using an electronic microscope in the following manner was 0.036 μm.

After a protective layer of carbon and Pt was formed on the conductive member, a specimen with a width of approximately 10 μm and a thickness of approximately 100 nm was manufactured in a focused ion beam system (trade name: FB-2100) manufactured by HITACHI, Ltd., a cross-section of the conductive layer was observed using a scanning transmission electronic microscope (trade name: HD-2300, applied voltage: 200 kV) manufactured by HITACHI, Ltd., the thickness was measured at five places on the conductive layer, and the average film thickness was computed in a form of an arithmetic average value. The average film thickness was computed by measuring the thickness of only the matrix component in which the metallic nanowires were not present.

Meanwhile, the conductive member with the protective layer was subjected to the measurement of the average film thickness, but the conductive member without the protective layer was subjected to other performance evaluations.

As a result of a measurement at 25° C. using a DM-701 (the same as described above), the water droplet contact angle on the surface of the conductive layer was 30°.

<<Patterning>>

A patterning treatment was carried out on the non-patterned conductive member obtained above using the following method. WHT-3 and SQUEEGEE No. 4 yellow (both trade names) manufactured by MINO GROUP Co., Ltd. were used in screen printing. A silver nanowire etchant for forming patterns was formed by mixing a CP-48S-A liquid, a CP-48S-B liquid (all trade names, manufactured by FUJIFILM Corporation) and pure water so that the proportions became 1:1:1, and thickening the mixture using hydroxyethyl cellulose, and used as an ink for screen printing. A pattern mesh with a stripe pattern (line/space=50 μm/50 μm) was used.

After the etchant was supplied to a partial area in which the non-conductive area was formed so that the supply amount became 0.01 g/cm², the etchant was left to stand at 25° C. for 2 minutes. After that, a patterning treatment was carried out through water washing, and a conductive member 1 with the conductive layer including a conduction area and a non-conduction area was obtained.

The patterning treatment described above was carried out, thereby obtaining a patterned conductive member 1 with the conductive layer including a conductive area and a non-conductive area.

(Preparation of Conductive Members 2 to 10)

Conductive members 2 to 21 and conductive members C-3 and C-4 were obtained in a manner substantially similar to the preparation of the conductive member 1 except that the tetraalkoxy compound, the organoalkoxy compound, or both compounds described in Table 1 were used in an amount described below instead of tetraethoxysilane and 3-glycidoxypropyltrimethoxysilane in the solution of the alkoxide compound used in the preparation of the conductive member 1. Meanwhile, the average film thicknesses in Table 1 are values measured using an electronic microscope.

TABLE 1

| | Tetraalkoxy Compound | Organoalkoxy Compound | Mass ratio of Tetraalkoxy Compound/ | Av. Thk. |
|---|---|---|---|---|
| C.M. No. | (used amount: parts by mass) | (used amount: parts by mass) | Organoalkoxy Compound | (μm) |
| 1 | Tetraethoxysilane (2.50) | 3-Glycidoxypropyltrimethoxysilane (2.50) | 1.000/1 | 0.036 |
| 2 | Tetraethoxysilane (0.02) | 3-Glycidoxypropyltrimethoxysilane (4.98) | 0.004/1 | 0.032 |
| 3 | Tetraethoxysilane (0.06) | 3-Glycidoxypropyltrimethoxysilane (4.94) | 0.012/1 | 0.033 |
| 4 | Tetraethoxysilane (0.15) | 3-Glycidoxypropyltrimethoxysilane (4.85) | 0.031/1 | 0.033 |
| 5 | Tetraethoxysilane (0.30) | 3-Glycidoxypropyltrimethoxysilane (4.70) | 0.064/1 | 0.034 |
| 6 | Tetraethoxysilane (1.00) | 3-Glycidoxypropyltrimethoxysilane (4.00) | 0.250/1 | 0.035 |
| 7 | Tetraethoxysilane (1.50) | 3-Glycidoxypropyltrimethoxysilane (3.50) | 0.423/1 | 0.035 |
| 8 | Tetraethoxysilane (3.00) | 3-Glycidoxypropyltrimethoxysilane (2.00) | 1.50/1 | 0.036 |
| 9 | Tetraethoxysilane (3.50) | 3-Glycidoxypropyltrimethoxysilane (1.50) | 2.33/1 | 0.037 |
| 10 | Tetraethoxysilane (4.00) | 3-Glycidoxypropyltrimethoxysilane (1.00) | 4.00/1 | 0.037 |
| 11 | Tetraethoxysilane (4.70) | 3-Glycidoxypropyltrimethoxysilane (0.30) | 15.7/1 | 0.038 |
| 12 | Tetraethoxysilane (4.85) | 3-Glycidoxypropyltrimethoxysilane (0.15) | 32.3/1 | 0.038 |
| 13 | Tetraethoxysilane (4.94) | 3-Glycidoxypropyltrimethoxysilane (0.06) | 82.3/1 | 0.039 |
| 14 | Tetraethoxysilane (4.98) | 3-Glycidoxypropyltrimethoxysilane (0.02) | 249/1 | 0.039 |
| 15 | Tetraethoxysilane (2.50) | Diethyldimethoxysilane (2.50) | 0.423/1 | 0.027 |
| 16 | Tetraethoxysilane (2.50) | Ureidopropyltriethoxysilane (2.50) | 0.423/1 | 0.023 |
| 17 | Tetramethoxysilane (2.50) | 3-Glycidoxypropyltrimethoxysilane (2.50) | 0.423/1 | 0.018 |
| 18 | Tetrapropoxy titanate (2.50) | 3-Glycidoxypropyltrimethoxysilane (2.50) | 0.423/1 | 0.030 |
| 19 | Tetraethoxy zirconate (2.50) | 3-Glycidoxypropyltrimethoxysilane (2.50) | 0.423/1 | 0.031 |
| 20 | Tetramethoxysilane (2.50) | Diethyldimethoxysilane (2.50) | 1.000/1 | 0.038 |
| 21 | Tetramethoxysilane (2.50) | Ureidopropyltriethoxysilane (2.50) | 1.000/1 | 0.037 |
| C3 | Tetraethoxysilane (2.50) | none | 1.00/0 | 0.032 |
| C4 | none | 3-Glycidoxypropyltrimethoxysilane (5.00) | 0.000/1 | 0.040 |

In Table 1, the abbreviation “C.M.No.” denotes “Number of conductive member”, and the abbreviation “Av. Thk.” denotes “Average film thickness of conductive layer”.

(Conductive Member C1)

A conductive member C1 was obtained in a manner substantially similar to the preparation of the conductive member 1 except that the sol-gel solution was not added in the preparation of the conductive member 1. The average film thickness of the conductive layer was 0.002 μm.

(Conductive Member C2)

A conductive member C2 was obtained in a manner substantially similar to the preparation of the conductive member 1 except that the sol-gel solution was changed to the following solution A in the preparation of the conductive member 1. The average film thickness of the conductive layer was 0.150 μm.

<Solution A>

| | |
|---|---|
| Polyvinyl pyrrolidone | 5.0 parts |
| Distilled water | 14.0 parts |

(Preparation of Conductive Member C5)

A conductive member C5 was obtained in a manner substantially similar to the preparation of the conductive member 1 except that the sol-gel solution was changed to the following solution B and the conductive layer 20 was exposed to i rays (365 nm) from an ultrahigh-pressure mercury lamp in a nitrogen atmosphere at an exposure value of 40 mJ/cm² in the preparation of the conductive member 1. The average film thickness of the conductive layer was 0.230 μm.

<Solution B>

| | |
|---|---|
| Dipentaerythritol hexaacrylate | 10.0 parts |
| Photopolymerization initiator: 2,4-bis-(trichloromethyl)-6-[4- | 0.4 parts |
| {N,N-bis(ethoxycarbonylmethyl)amino}-3-bromophenyl]-s- | |
| triazine | |
| Methyl ethyl ketone | 13.6 parts |

(Preparation of Conductive Members 22 to 41)

Conductive members 22 to 41 were obtained in a manner substantially similar to the case of the conductive member 1 except that the amounts of the alkoxide solution and the silver nanowire aqueous dispersion liquid (1) that were mixed to prepare the sol-gel coating liquid, the amount of the silver formed on the substrate, and the total application amount of the solid content were changed as described in Table 2 in the preparation of the conductive member 1. The film thicknesses in Table 2 are values measured using a stylus type surface profiler, and the average thicknesses are values measured using an electronic microscope.

TABLE 2

| | Conductive Layer | | | | | | |
|---|---|---|---|---|---|---|---|
| | Sol-gel M.A. | M.A.M.naW.D | Mass Ratio of T.A.Comp./Silver | C.Silv.A. | C. A.T.S. | Film Thickness | Av. Thk. |
| C.M.No. | (parts) | (parts) | nanowire | (g/m²) | (g/m²) | (μm) | (μm) |
| 22 | 0.16 | 19.84 | 0.25/1 | 0.020 | 0.025 | 0.020 | 0.003 |
| 23 | 0.31 | 19.69 | 0.5/1 | 0.020 | 0.030 | 0.025 | 0.005 |
| 24 | 0.62 | 19.38 | 1/1 | 0.020 | 0.040 | 0.030 | 0.007 |
| 25 | 0.92 | 19.08 | 1.5/1 | 0.020 | 0.050 | 0.035 | 0.010 |
| 26 | 1.20 | 18.80 | 2/1 | 0.020 | 0.060 | 0.040 | 0.012 |
| 27 | 2.27 | 17.73 | 4/1 | 0.020 | 0.100 | 0.060 | 0.023 |
| 28 | 4.08 | 15.92 | 8/1 | 0.020 | 0.180 | 0.100 | 0.044 |
| 29 | 4.85 | 15.15 | 10/1 | 0.020 | 0.220 | 0.120 | 0.054 |
| 30 | 6.49 | 13.51 | 15/1 | 0.020 | 0.320 | 0.170 | 0.081 |
| 31 | 7.31 | 12.69 | 18/1 | 0.020 | 0.380 | 0.200 | 0.096 |
| 32 | 8.89 | 11.11 | 25/1 | 0.020 | 0.520 | 0.270 | 0.130 |
| 33 | 9.80 | 10.20 | 30/1 | 0.020 | 0.620 | 0.320 | 0.160 |
| 34 | 3.44 | 16.56 | 6.5/1 | 0.035 | 0.263 | 0.150 | 0.063 |
| 35 | 3.44 | 16.56 | 6.5/1 | 0.018 | 0.135 | 0.075 | 0.032 |
| 36 | 3.44 | 16.56 | 6.5/1 | 0.015 | 0.113 | 0.065 | 0.027 |
| 37 | 3.44 | 16.56 | 6.5/1 | 0.013 | 0.098 | 0.055 | 0.023 |
| 38 | 3.44 | 16.56 | 6.5/1 | 0.010 | 0.075 | 0.042 | 0.018 |
| 39 | 3.44 | 16.56 | 6.5/1 | 0.008 | 0.060 | 0.035 | 0.014 |
| 40 | 3.44 | 16.56 | 6.5/1 | 0.005 | 0.038 | 0.022 | 0.009 |
| 41 | 3.44 | 16.56 | 6.5/1 | 0.002 | 0.015 | 0.010 | 0.004 |

In Table 1, the abbreviation “C.M.No.” denotes “Number of conductive member”, the abbreviation “Sol-gel M.A.” denotes “Mixed amount of sol-gel solution”, the abbreviation “M.A.M.naW.D” denotes “Mixed amount of metallic nanowire aqueous dispersion”, the abbreviation “T.A.Comp.” denotes “Total amount of Tetraalkoxy compound and Organoalkoxy compound”, the abbreviation “C.Silv.A.” denotes “Coated amount of silver”, the abbreviation “C.A.T.S.” denotes “Coated amount of total solid”, and the abbreviation “Av. Thk.” denotes “Average film thickness of conductive layer”.

(Conductive Member 42)

A conductive member 42 was obtained in a manner substantially similar to the preparation of the conductive member 1 except that the PET substrate 101 was changed to the glass substrate manufactured in Preparation Example 2.

(Conductive Member 1R)

The preparation of the conductive member 1 was carried out again, thereby obtaining a conductive member 1R.

<<Evaluation>>

For the each obtained conductive members, the surface resistivity, optical characteristics (light transmittance, haze), film strength, abrasion resistance, heat resistance, moisture and heat resistance, bendability, etchability and the water droplet contact angle of the conductive layer were respectively evaluated, and the results were described in Tables 3 and 4. Meanwhile, the non-patterned conductive members were used in the evaluation.

<Surface Resistivity>

The surface resistivity of the conductive area in the conductive member was measured using LORESTA-GP MCP-T600; trade name, manufactured by MITSUBISHI CHEMICAL Corporation. The surface resistivity was calculated as an average value from five values of surface resistivity measured at five central positions randomly selected from the conductive region of 10 cm×10 cm-sized specimen, and rated using the following ranks based on the value.
Rank 5: the surface resistivity of less than 100Ω/□, an extremely outstanding level
Rank 4: the surface resistivity of from 100Ω/□ to less than 150Ω/□, an outstanding level
Rank 3: the surface resistivity of from 150Ω/□ to less than 200Ω/□, an allowable level
Rank 2: the surface resistivity of from 200Ω/□ to less than 1000Ω/□, a slightly problematic level
Rank 1: the surface resistivity of 1000Ω/□ or more, a problematic level

<Optical Characteristics (Light Transmittance)>

The light transmittance (%) of a portion corresponding to the conductive area of the conductive member and the light transmittance (%) of the PET substrates 101 (Conductive members 1 to 41) or the glass substrate (Conductive member 42) on which the conductive layer 20 was not yet to be formed were measured using a HAZE-GARD PLUS; trade name, manufactured by GARTNER, Inc., the transmittance of a transparent conductive film was converted from the ratio, and rated using the following ranks. The measurement was made with respect to CIE luminosity function y under a C light source at a measurement angle of 0°, and the transmittance was rated using the following ranks.
Rank A: the transmittance of 90% or more, a favorable level
Rank B: the transmittance of from 85% to less than 90%, a slightly problematic level

<Optical Characteristics (Haze)>

The haze value of the rectangular solid-exposed region of the obtained conductive film was measured using a HAZE-GARD PLUS described above. The haze value was calculated as an average value from five values measured at five central positions randomly selected from the conductive region of 10 cm×10 cm-sized specimen, and rated using the following ranks.
Rank A: the haze of less than 1.5%, an outstanding level
Rank B: the haze of from 1.5% to less than 2.0%, a favorable level
Rank C: the haze of from 2.0% to less than 2.5%, a slightly problematic level
Rank D: the haze of 2.5% or more, a problematic level

<Film Strength>

After specimens were scratched 10 mm under a condition of a load of 500 g using a pencil scratching hardness tester (manufactured by TOYO SEIKI SEISAKU-SHO, Ltd., NP type; trade name) set with Japan Paint Inspection and Testing Association-certified pencils for pencil scratching (hardness HB and hardness B) according to ISO/DIS 15184: 1996, exposure and development thereof were carried out under the following conditions, the scratched portions were observed using a digital microscope (VHX-600; trade name, manufactured by KEYENCE Corporation, magnification of 2,000 times), and rated using the following ranks. Meanwhile, there was no cut conductive fibers observed in the conductive layer of Level 3 or higher, and thus Level 3 or higher were problem-free levels at which practical conduction can be ensured.

[Evaluation Criteria]
Rank 5: no observed scratch after scratching by a pencil with a hardness of 2H, an extremely outstanding level
Rank 4: conductive fibers were cut by scratching by a pencil with a hardness of 2H, and scratches were observed, but conductive fibers remained, and there was no exposed surface of the base material, an outstanding level
Rank 3: there were surfaces of the base material exposed by scratching by a pencil with a hardness of 2H, but conductive fibers remained after scratching by a pencil with a hardness of HB, and there was no exposed surface of the base material, a favorable level
Rank 2: the conductive layer was cut by a pencil with a hardness of HB, and exposed surfaces of the base material were partially observed, a problematic level
Rank 1: the conductive layer was cut by a pencil with a hardness of HB, and almost all the surface of the base material was exposed, a problematic level

<Abrasion Resistance>

An abrasion treatment in which a surface of the obtained conductive layer in the conductive member was reciprocally rubbed 50 reciprocations with a load of 500 g using a 20 mm×20 mm-sized FC gauze (described above) piece, the generation of scratches after the treatment was observed, and the change rate of the surface resistivity (the surface resistivity after the abrasion treatment/the surface resistivity before the abrasion treatment) was computed. In the abrasion test, a continuous loading scratching intensity tester TYPE 18S; trade name, manufactured by SHINTO SCIENTIFIC Co., Ltd. was used, and the surface resistivity was measured using LORESTA-GP MCP-T600 (described above). Conductive members with no scratch and a smaller change rate of the surface resistivity (approaching to 1) are excellent in terms of abrasion resistance. In the table, the abbreviation “OL” denotes that the surface resistivity is 1.0×10⁸Ω/□ or more and substantially no conductive.

<Heat Resistance>

A heating treatment in which the conductive member was heated at 150° C. for 60 minutes was carried out, and the change rate of the surface resistivity (the surface resistivity after the heat resistance test/the surface resistivity before the heat resistance test, also referred as resistivity change) and the change degree of the haze (the haze after the heat resistance test—the haze before the heat resistance test, also referred as haze change value) were computed. The surface resistivity was measured using LORESTA-GP MCP-T600 (described above), and the haze was measured using a HAZE-GARD PLUS (described above). As the change rate of the surface resistivity approaches to 1, and the change degree of the haze decreases, the heat resistance is excellent.

<Moisture and Heat Resistance>

A moisture and heat treatment in which the conductive member was left to stand for 240 hours at 60° C. under an environment of 90RH % was carried out, and the change rate (the surface resistivity after the moisture and heat resistance test/the surface resistivity before the moisture and heat resistance test) of the surface resistivity and the change degree (the haze after the moisture and heat resistance test—the haze before the moisture and heat resistance test) of the haze were computed. The surface resistivity was measured using LORESTA-GP MCP-T600 (described above), and the haze was measured using a HAZE-GARD PLUS (described above). As the change rate of the surface resistivity approaches to 1, and the change degree of the haze decreases, the moisture and heat resistance is excellent.

<Bendability>

A bending treatment in which the obtained conductive member was bent 20 times on a cylindrical mandrel having a diameter of 10 mm using a cylindrical mandrel bending tester

(for example, a bending tester manufactured by COTEC Corporation) was carried out, the presence of cracks before and after the bending treatment was observed, and the change rate of the surface resistivity (the surface resistivity after the bending test/the surface resistivity before the bending test) was carried out. The presence of cracks was checked visually using an optical microscope, and the surface resistivity was measured using LORESTA-GP MCP-T600 (described above). Conductive members with no crack and the change rate of the surface resistivity approaching 1 are excellent in terms of bendability. It is noted that the conductive member used glass substrate was not evaluated in the term of bendability.

<Etchability>

The obtained conductive member was immersed in a solution (etchant) formed by mixing the CP-48S-A liquid, the CP-48S-B liquid (all trade names, manufactured by FUJIFILM Corporation) and pure water so that the proportions became 1:1:1 which had been used to form the patterns at 25° C., then, washed using flowing water, and dried. The surface resistivity was measured using LORESTA-GP MCP-T600 (the same as described above). The haze value was measured using a HAZE-GARD PLUS (described above).

The etchability improves as the surface resistivity increases and the A haze value (the difference in the haze value before and after the immersion) increase after the immersion in the etchant. Therefore, the immersion time in the etchant necessary for the surface resistivity to become 1.0×10⁸Ω/□ or more and the haze change value to become 0.4% or more was obtained, and rated using the following ranks.
Rank 5: the immersion time in the etchant necessary for the surface resistivity to become 1.0×10⁸Ω/□ or more and the haze change value to become 0.4% or more is less than 30 seconds; an extremely outstanding level
Rank 4: the immersion time in the etchant is 30 seconds to less than 60 seconds; an outstanding level
Rank 3: the immersion time in the etchant is 60 seconds to less than 120 seconds; a favorable level
Rank 2: the immersion time in the etchant is 120 seconds to less than 180 seconds; a practically problematic level
Rank 1: the immersion time in the etchant is 180 seconds or more; an extremely practically problematic level

<Water Droplet Contact Angle>

The water droplet contact angle on the outer surface of the conductive layer was measured at 25° C. using a DM-701 (the same as described above).

TABLE 3

| | Performance Evaluation | | | | | | | | | | | |
|---|---|---|---|---|---|---|---|---|---|---|---|---|
| Example | | | | Film | Abr. | Heat Resistance | | Moist. Heat Resist. | | | | |
| Number | S.R. | L.Trans. | Haze | Strength | Resist. | C.R.S.R. | C.D.Haze | C.R.S.R. | C.D.Haze | Bendability | Etch. P. | W.C.A |
| 1 | 4 | A | B | 4 | 1.19 | 1.38 | 0.27 | 1.31 | 0.28 | 1.10 | 5 | 30 |
| 2 | 4 | A | B | 3 | 2.98 | 1.43 | 0.28 | 1.29 | 0.29 | 1.04 | 5 | 45 |
| 3 | 4 | A | B | 3 | 2.53 | 1.32 | 0.30 | 1.38 | 0.33 | 1.04 | 5 | 41 |
| 4 | 4 | A | B | 3 | 2.01 | 1.46 | 0.29 | 1.35 | 0.31 | 1.07 | 5 | 38 |
| 5 | 4 | A | B | 3 | 1.85 | 1.53 | 0.21 | 1.39 | 0.28 | 1.08 | 5 | 35 |
| 6 | 4 | A | B | 3 | 1.59 | 1.43 | 0.31 | 1.33 | 0.26 | 1.08 | 5 | 32 |
| 7 | 4 | A | B | 4 | 1.38 | 1.41 | 0.32 | 1.31 | 0.30 | 1.09 | 5 | 28 |
| 8 | 4 | A | B | 4 | 1.22 | 1.52 | 0.27 | 1.31 | 0.28 | 1.16 | 5 | 26 |
| 9 | 4 | A | B | 4 | 1.17 | 1.43 | 0.26 | 1.30 | 0.25 | 1.28 | 5 | 22 |
| 10 | 4 | A | B | 4 | 1.15 | 1.55 | 0.24 | 1.29 | 0.26 | 1.36 | 5 | 20 |
| 11 | 4 | A | B | 4 | 1.15 | 1.41 | 0.29 | 1.35 | 0.34 | 1.39 | 5 | 18 |
| 12 | 4 | A | B | 4 | 1.13 | 1.53 | 0.25 | 1.37 | 0.31 | 1.52 | 5 | 17 |
| 13 | 4 | A | B | 4 | 1.12 | 1.46 | 0.29 | 1.28 | 0.32 | 1.64 | 5 | 15 |
| 14 | 4 | A | B | 4 | 1.12 | 1.49 | 0.25 | 1.33 | 0.29 | 1.78 | 5 | 12 |
| 15 | 4 | A | B | 4 | 1.22 | 1.48 | 0.28 | 1.34 | 0.28 | 1.11 | 5 | 40 |
| 16 | 4 | A | B | 4 | 1.18 | 1.50 | 0.24 | 1.29 | 0.29 | 1.10 | 5 | 22 |
| 17 | 4 | A | B | 4 | 1.16 | 1.38 | 0.21 | 1.38 | 0.35 | 1.18 | 5 | 28 |
| 18 | 4 | A | B | 4 | 1.26 | 1.34 | 0.28 | 1.41 | 0.33 | 1.11 | 5 | 32 |
| 19 | 4 | A | B | 4 | 1.25 | 1.64 | 0.24 | 1.36 | 0.35 | 1.13 | 5 | 34 |
| 20 | 4 | A | B | 4 | 1.17 | 1.29 | 0.28 | 1.29 | 0.28 | 1.15 | 5 | 42 |
| 21 | 4 | A | B | 4 | 1.17 | 1.31 | 0.21 | 1.31 | 0.26 | 1.13 | 5 | 20 |
| C1 | 5 | A | B | 1 | OL | 6.25 | 0.68 | 10.5 | 0.95 | 2.63 | 5 | 12 |
| C2 | 2 | C | C | 1 | 300 | 4.89 | 0.52 | 5.23 | 0.59 | 1.25 | 2 | 10 |
| C3 | 4 | A | B | 4 | 1.10 | 1.39 | 0.20 | 1.21 | 0.21 | 2.05 | 5 | 10 |
| C4 | 4 | A | B | 3 | 4.90 | 1.42 | 0.28 | 1.23 | 0.28 | 1.02 | 5 | 48 |
| C5 | 1 | B | B | 5 | 1.01 | 1.02 | 0.15 | 1.09 | 0.09 | 2.88 | 1 | 60 |

TABLE 4

| | Performance Evaluation | | | | | | | | | |
|---|---|---|---|---|---|---|---|---|---|---|
| Example | | | | Film | Abr. | Heat Resistance | | Moist. Heat Resist. | | |
| Number | S.R. | L.Trans. | Haze | Strength | Resist. | C.R.S.R. | C.D.Haze | C.R.S.R. | C.D.Haze | Bendability |
| 22 | 5 | A | B | 2 | 50.2 | 3.90 | 0.48 | 3.80 | 0.45 | 1.10 |
| 23 | 5 | A | B | 2 | 46.2 | 3.25 | 0.45 | 3.24 | 0.42 | 1.11 |
| 24 | 4 | A | B | 3 | 28.7 | 2.80 | 0.40 | 2.85 | 0.39 | 1.16 |
| 25 | 4 | A | B | 3 | 18.6 | 2.53 | 0.36 | 2.24 | 0.35 | 1.10 |
| 26 | 4 | A | B | 4 | 10.2 | 2.20 | 0.37 | 2.08 | 0.31 | 1.08 |
| 27 | 4 | A | B | 4 | 5.62 | 1.91 | 0.32 | 1.84 | 0.28 | 1.04 |
| 1R | 4 | A | B | 4 | 1.22 | 1.45 | 0.28 | 1.37 | 0.28 | 1.03 |
| 28 | 4 | A | B | 4 | 1.10 | 1.25 | 0.28 | 1.53 | 0.21 | 1.02 |
| 29 | 3 | A | B | 5 | 1.06 | 1.18 | 0.22 | 1.24 | 0.17 | 1.01 |
| 30 | 3 | A | B | 5 | 1.04 | 1.12 | 0.18 | 1.18 | 0.13 | 1.08 |
| 31 | 2 | A | B | 5 | 1.04 | 1.10 | 0.15 | 1.11 | 0.11 | 1.12 |
| 32 | 2 | A | C | 5 | 1.03 | 1.08 | 0.10 | 1.07 | 0.09 | 1.15 |
| 33 | 2 | A | C | 5 | 1.00 | 1.06 | 0.05 | 1.02 | 0.05 | 1.17 |
| 34 | 5 | B | C | 5 | 1.25 | 1.70 | 0.31 | 1.38 | 0.31 | 1.04 |
| 35 | 4 | A | B | 4 | 1.23 | 1.50 | 0.28 | 1.35 | 0.30 | 1.05 |
| 36 | 4 | A | A | 4 | 1.30 | 1.53 | 0.29 | 1.35 | 0.26 | 1.03 |
| 37 | 3 | A | A | 4 | 1.32 | 1.58 | 0.30 | 1.36 | 0.38 | 1.07 |
| 38 | 3 | A | A | 4 | 1.41 | 1.65 | 0.33 | 1.32 | 0.31 | 1.04 |
| 39 | 2 | A | A | 4 | 1.40 | 1.52 | 0.35 | 1.34 | 0.32 | 1.03 |
| 40 | 2 | A | A | 3 | 1.55 | 1.49 | 0.39 | 1.30 | 0.37 | 1.02 |
| 41 | 2 | A | A | 3 | 1.68 | 1.48 | 0.37 | 1.28 | 0.36 | 1.06 |
| 42 | 4 | A | B | 4 | 1.20 | 1.48 | 0.21 | 1.29 | 0.30 | — |

In Tables 3 and 4, the abbreviation “S.R.” denotes “Surface resistivity”, the abbreviation “L. Trans.” denotes “Light transmittance”, the abbreviation “Abr. Resist.” denotes “Abrasion resistance”, the abbreviation “Moist. Heat Resist.” denotes “Moisture and heat resistance”, the abbreviation “C.R.S.R.” denotes “Change rate of surface resistivity”, the abbreviation “C.D. Haze” denotes “Change degree of haze”, the abbreviation “Etch. P.” denotes “Etching properties”, and the abbreviation “W.C.A” denotes “Water droplet contact angle on a surface of conductive layer”.

The conductive members C-3 and C-4 respectively have a conductive layer including the cured sol-gel substance formed solely using the tetraalkoxy compound or the organoalkoxy compound. It is found from the results described in Table 3 that the conductive member C-3 has poor bendability and the conductive member C-4 has poor abrasion resistance. It is found that, in contrast to the above conductive members, the conductive members 1 to 21 according to an embodiment of the invention are excellent in terms of bendability and abrasion resistance and, simultaneously, have excellent performance in terms of each of surface resistivity, light transmittance, haze, film strength, heat resistance, and moisture and heat resistance.

Furthermore, the following can be understood from the results described in Table 4.

It is found from the evaluation results of the conductive members 22 to 33 and the conductive member 1R in which the application amount of the silver nanowires in the conductive layer is identical and the mass ratio of the total content of the tetraalkoxy compound and the organoalkoxy compound to the content of the silver nanowires is changed that, in a case in which the mass ratio of the total content of the tetraalkoxy compound and the organoalkoxy compound to the content of the silver nanowires is in a range of 2/1 to 8/1, a conductive member which exhibits favorable performance and is most balanced in terms of each of surface resistivity, light transmittance, haze, abrasion resistance, moisture and heat resistance and bendability is obtained.

In addition, it is found from the evaluation results of the conductive members 34 to 42 and the conductive member 1R in which the mass ratio of the total content of the tetraalkoxy compound and the organoalkoxy compound to the content of the silver nanowires is identical and the application amount of the silver nanowires is changed that, in a case in which the application amount of the silver nanowires is in a range of 0.015 g/m² to 0.02 g/m², a conductive member which exhibits favorable performance and is most balanced in terms of each of surface resistivity, light transmittance, haze, abrasion resistance, moisture and heat resistance and bendability is obtained.

(Preparation of Conductive Members 43 to 50)

Conductive members 43 to 50 were obtained in a manner substantially similar to the preparation of the conductive member 1 except that silver nanowire aqueous dispersion liquid (2) to (9) having different average long-axis lengths and different average short-axis lengths, which are described in Table 5, were used instead of the silver nanowire aqueous dispersion liquid (1) used in the preparation the conductive member 1.

TABLE 5

| Example | Aqueous Dispersion Liquid of Silver Nanowire | | |
|---|---|---|---|
| Number | Number | Long axis length (μm) | Short axis length (nm) |
| 43 | (2) | 22.0 | 32.5 |
| 44 | (3) | 25.5 | 45.9 |
| 45 | (4) | 18.5 | 62.7 |
| 46 | (5) | 15.5 | 20.4 |
| 47 | (6) | 8.0 | 18.7 |
| 48 | (7) | 10.8 | 28.9 |
| 49 | (8) | 9.2 | 47.8 |
| 50 | (9) | 8.8 | 61.2 |

(Preparation of Conductive Member 51)

After the surface of the second adhesion layer 32 in the PET substrate 101 manufactured in Preparation Example 3 was subjected to a corona discharge treatment, a 0.1% aqueous solution of N-β(aminoethyl) γ-aminopropyltrimethoxysilane (KBM-603 (the same as described above)) was applied using a bar coating method so that the application amount of the solid content became 0.007 g/m² and dried at 175° C. for 1 minute, thereby forming a functional layer 33. Thereby, a PET substrate 102 including the intermediate layer 30 made up of a trilayer configuration of the adhesion layer 31, the adhesion layer 32 and the functional layer 33 in the configuration illustrated in FIG. 2 was manufactured.

The same conductive layer 20 as the conductive layer in the conductive member 1 was formed on the PET substrate 102, thereby preparing a non-patterned conductive member 51 illustrated in the cross-sectional view of FIG. 2. Patterning was carried out in a manner substantially similar to the case of the conductive member 1, thereby obtaining a conductive member 51.

(Preparation of Conductive Members 52 to 59)

Conductive members 52 to 59 were obtained in a manner substantially similar to the preparation of the conductive member 51 except that KBM 603 (the same as described above) was changed to the following compounds in the formation of the functional layer 33 in the PET substrate 102 used in the conductive member 51.

Conductive member 52: Ureidopropyltriethoxysilane

Conductive member 53: 3-Aminopropyltriethoxysilane

Conductive member 54: 3-Mercaptopropyltrimethoxysilane

Conductive member 55: Polyacrylic acid (Weight average molecular weight: 50,000)

Conductive member 56: Homopolymer of PHOSMER-M™ (Weight average molecular weight: 20,000)

Conductive member 57: Polyacrylamide (Weight average molecular weight: 100,000)

Conductive member 58: Poly(sodium p-styrenesulfonate (Weight average molecular weight: 50,000)

Conductive member 59: Bis(hexamethylene)triamine

(Preparation of Conductive Members C6 to C13)

Conductive members C6 to C13 were obtained in a manner substantially similar to the preparation of the conductive member C2 except that the silver nanowire aqueous dispersion liquid (2) to (9) was used instead of the silver nanowire aqueous dispersion liquid (1) used in the preparation of the conductive member C2.

<<Evaluation>>

For the obtained respective conductive members, the surface resistivity, optical characteristics (light transmittance, haze), film strength, abrasion resistance, heat resistance, moisture and heat resistance, and bendability were evaluated using the same methods as described above. The results are described in Table 6.

TABLE 6

| | Performance Evaluation | | | | | | | | | |
|---|---|---|---|---|---|---|---|---|---|---|
| Example | | | | Film | Abr. | Heat Resistance | | Moist. Heat Resist. | | |
| Number | S.R. | L.Trans. | Haze | Strength | Resist. | C.R.S.R. | C.D.Haze | C.R.S.R. | C.D.Haze | Bendability |
| 43 | 4 | A | B | 5 | 1.31 | 1.52 | 0.25 | 1.36 | 0.31 | 1.05 |
| 44 | 4 | B | C | 4 | 1.33 | 1.38 | 0.22 | 1.31 | 0.28 | 1.03 |
| 45 | 3 | B | C | 3 | 1.58 | 1.27 | 0.18 | 1.26 | 0.22 | 1.13 |
| 46 | 4 | A | B | 5 | 1.27 | 1.26 | 0.19 | 1.23 | 0.21 | 1.05 |
| 47 | 4 | A | A | 5 | 1.18 | 1.45 | 0.24 | 1.34 | 0.30 | 1.02 |
| 48 | 4 | A | B | 5 | 1.25 | 1.42 | 0.23 | 1.31 | 0.27 | 1.05 |
| 49 | 4 | A | C | 4 | 1.48 | 1.36 | 0.20 | 1.31 | 0.25 | 1.06 |
| 50 | 3 | A | C | 3 | 1.62 | 1.25 | 0.15 | 1.28 | 0.25 | 1.09 |
| 51 | 4 | A | B | 5 | 1.15 | 1.22 | 0.15 | 1.28 | 0.17 | 1.04 |
| 52 | 4 | A | B | 5 | 1.20 | 1.25 | 0.20 | 1.09 | 0.19 | 1.05 |
| 53 | 4 | A | B | 5 | 1.15 | 1.23 | 0.18 | 1.27 | 0.16 | 1.07 |
| 54 | 3 | A | B | 5 | 1.13 | 1.18 | 0.10 | 1.15 | 0.12 | 1.02 |
| 55 | 4 | A | B | 5 | 1.23 | 1.24 | 0.18 | 1.29 | 0.18 | 1.03 |
| 56 | 3 | A | B | 5 | 1.15 | 1.20 | 0.11 | 1.16 | 0.12 | 1.03 |
| 57 | 4 | A | B | 5 | 1.18 | 1.65 | 0.19 | 1.30 | 0.16 | 1.04 |
| 58 | 4 | A | B | 5 | 1.16 | 1.52 | 0.14 | 1.23 | 0.18 | 1.02 |
| 59 | 4 | A | B | 5 | 1.15 | 1.49 | 0.20 | 1.25 | 0.16 | 1.03 |
| C6 | 4 | A | B | 1 | 250 | 4.52 | 0.48 | 6.36 | 0.71 | 1.65 |
| C7 | 4 | B | C | 1 | 220 | 2.68 | 0.32 | 4.61 | 0.52 | 1.43 |
| C8 | 3 | B | C | 1 | 200 | 1.57 | 0.18 | 1.76 | 0.37 | 1.23 |
| C9 | 4 | A | B | 1 | 260 | 6.26 | 0.55 | 9.27 | 0.88 | 1.77 |
| C10 | 4 | A | A | 1 | 180 | 7.61 | 0.62 | 11.3 | 0.92 | 1.82 |
| C11 | 4 | A | B | 1 | 240 | 4.72 | 0.50 | 6.62 | 0.75 | 1.75 |
| C12 | 4 | A | C | 1 | 260 | 2.16 | 0.29 | 4.44 | 0.48 | 1.46 |
| C13 | 3 | A | C | 1 | 300 | 1.51 | 0.19 | 1.68 | 0.39 | 1.29 |

In Table 6, the abbreviation “S.R.” denotes “Surface resistivity”, the abbreviation “L. Trans.” denotes “Light transmittance”, the abbreviation “Abr. Resist.” denotes “Abrasion resistance”, the abbreviation “Moist. Heat Resist.” denotes “Moisture and heat resistance”, the abbreviation “C.R.S.R.” denotes “Change rate of surface resistivity”, and the abbreviation “C.D. Haze” denotes “Change degree of haze”.

The following can be understood from the results described in Table 6.

It is found from the evaluation results of the conductive members 43 to 50 and the conductive member 1 that the conductive members in which the conductive layer including the silver nanowires with an average short-axis length in a range of 30 nm or less is used have particularly excellent performance in terms of light transmittance, haze, film strength and abrasion resistance.

In addition, it is found from the evaluation results of the conductive members 51 to 59 that, when a functional layer including a compound having an amide group, an amino group, a mercapto group, a carboxylic acid group, a sulfonic acid group, a phosphoric acid group or a phosphonic acid group as the intermediate layer in contact with the conductive layer is provided, the conductive film can be applied to the substrate without any problem.

(Preparation of Conductive Member 60)

A conductive member 60 was obtained in a manner substantially similar to the conductive member 1 except that silver nanowire aqueous dispersion liquid (10) obtained by diluting the silver nanowire-dispersed liquid described in Examples 1 and 2 (Paragraph [0151] on Page 8 to Paragraph [0160] on Page 9) of U.S. Patent Application Publication No. 2011/0174190A1 to 0.45% using distilled water was used instead of the silver nanowire aqueous dispersion liquid (1).

(Preparation of Conductive Members 61 to 70)

Conductive members 61 to 70 were obtained respectively in a manner substantially similar to the conductive member 6, 10, 27, 29, 30, 36, 37, 51, 52 or 53 except that the silver nanowire aqueous dispersion liquid (1) was changed to the silver nanowire aqueous dispersion liquid (10) as described below.

Conductive member 61: Binder configuration of Conductive member 6+Aqueous dispersion of silver nanowire (10)

Conductive member 62: Binder configuration of Conductive member 10+Aqueous dispersion of silver nanowire (10)

Conductive member 63: Binder configuration of Conductive member 27+Aqueous dispersion of silver nanowire (10)

Conductive member 64: Binder configuration of Conductive member 29+Aqueous dispersion of silver nanowire (10)

Conductive member 65: Binder configuration of Conductive member 30+Aqueous dispersion of silver nanowire (10)

Conductive member 66: Binder configuration of Conductive member 36+Aqueous dispersion of silver nanowire (10)

Conductive member 67: Binder configuration of Conductive member 37+Aqueous dispersion of silver nanowire (10)

Conductive member 68: Binder configuration of Conductive member 51+Aqueous dispersion of silver nanowire (10)

Conductive member 69: Binder configuration of Conductive member 52+Aqueous dispersion of silver nanowire (10)

Conductive member 70: Binder configuration of Conductive member 53+Aqueous dispersion of silver nanowire (10)

<<Evaluation>>

For the obtained respective conductive members, the surface resistivity, optical characteristics (light transmittance, haze), film strength, abrasion resistance, heat resistance, moisture and heat resistance and bendability were evaluated using the same methods as used above. The results are described in Table 7.

TABLE 7

| | Performance Evaluation | | | | | | | | | |
|---|---|---|---|---|---|---|---|---|---|---|
| Example | | | | Film | Abr. | Heat Resistance | | Moist. Heat Resist. | | |
| Number | S.R. | L.Trans. | Haze | Strength | Resist. | C.R.S.R. | C.D.Haze | C.R.S.R. | C.D.Haze | Bendability |
| 60 | 4 | A | B | 4 | 1.18 | 1.37 | 0.26 | 1.30 | 0.27 | 1.11 |
| 61 | 4 | A | B | 3 | 1.57 | 1.44 | 0.30 | 1.32 | 0.25 | 1.07 |
| 62 | 4 | A | B | 4 | 1.16 | 1.53 | 0.25 | 1.28 | 0.24 | 1.35 |
| 63 | 4 | A | B | 4 | 5.32 | 1.94 | 0.34 | 1.83 | 0.27 | 1.03 |
| 64 | 3 | A | B | 5 | 1.05 | 1.17 | 0.24 | 1.25 | 0.18 | 1.02 |
| 65 | 3 | A | B | 5 | 1.02 | 1.11 | 0.19 | 1.19 | 0.12 | 1.07 |
| 66 | 4 | A | A | 4 | 1.33 | 1.55 | 0.27 | 1.34 | 0.25 | 1.03 |
| 67 | 3 | A | A | 4 | 1.36 | 1.60 | 0.31 | 1.34 | 0.36 | 1.06 |
| 68 | 4 | A | B | 5 | 1.14 | 1.21 | 0.13 | 1.29 | 0.18 | 1.03 |
| 69 | 4 | A | B | 5 | 1.22 | 1.24 | 0.22 | 1.08 | 0.21 | 1.04 |
| 70 | 4 | A | B | 5 | 1.14 | 1.22 | 0.19 | 1.26 | 0.15 | 1.08 |

In Table 7, the abbreviation “S.R.” denotes “Surface resistivity”, the abbreviation “L. Trans.” denotes “Light transmittance”, the abbreviation “Abr. Resist.” denotes “Abrasion resistance”, the abbreviation “Moist. Heat Resist.” denotes “Moisture and heat resistance”, the abbreviation “C.R.S.R.” denotes “Change rate of surface resistivity”, and the abbreviation “C.D. Haze” denotes “Change degree of haze”.

The following can be understood from the results described in Table 7.

It is found from the evaluation results of the conductive members 60 to 70 that the conductive member that is an embodiment of the invention has excellent performance in terms of light transmittance, haze, film strength and abrasion resistance even when the silver nanowires described in U.S. Patent Application Publication No. 2011/0174190A1 are used.

<Production of an Integrated Solar Cell>

—Production of a (Super Straight-Type) Amorphous Solar Cell—

A conductive layer was formed on a glass substrate in a manner substantially similar to the conductive member 1, thereby forming a transparent conductive film. Here, a patterning treatment was not carried out so that the transparent conductive film with a uniform surface was formed. An approximately 15 nm-thick p-type amorphous silicon film, an approximately 350 nm-thick i-type amorphous silicon film, and an approximately 30 nm-thick n-type amorphous silicon film were formed on the top portion of the conductive film using a plasma CVD method, and a 20 nm-thick gallium-added zinc oxide layer and a 200 nm-thick silver layer were formed as rear surface reflection electrodes, thereby producing a photoelectric conversion element (integrated solar cell).

<Production of a (Substrate-Type) GIGS Solar Cell>

An approximately 500 nm-thick molybdenum electrode and an approximately 2.5 μm-thick Cu(In_{0.6}Ga_{0.4})Se₂ thin film which is a chalcopyrite-based semiconductor material were formed on a soda lime glass substrate using a direct-current magnetron sputtering method and a vacuum deposition method respectively, and an approximately 50 nm-thick cadmium sulfide thin film was formed on the thin film using a solution precipitation method.

The same conductive layer as the conductive layer 1 was formed on the cadmium sulfide thin film, and a transparent conductive film was formed on a glass substrate, thereby producing a photoelectric conversion element (CIGS solar cell).

For the respective produced solar cells, the conversion efficiency was evaluated in the following manner.

<Evaluation of the Solar Cell Characteristics (Conversion Efficiency)>

Pseudo solar light rays were radiated on the respective solar cells at an air mass (AM) of 1.5 and a radiation intensity of 100 mW/cm², thereby measuring the conversion efficiencies). As a result, all the elements exhibited a conversion efficiency of 9%.

From the results, it was found that, when the laminate for forming conductive films that is an embodiment of the invention is used to form transparent conductive films, a high conversion efficiency is obtained with all methods of integrated solar cells.

—Production of a Touch Panel—

A transparent conductive film was formed on a glass substrate in a manner substantially similar to the formation of the conductive layer in Example 1. A touch panel was produced using the obtained transparent conductive film and a method described in “Advanced Touch Panel Technologies” (published on Jul. 6, 2009 by Techno Times Co., Ltd.), “Technology and Development of Touch Panels” edited by Yuuji Mitani, (CMC Publishing Co., Ltd. (published in December 2004)), “FPD International 2009 Forum T-11 lecture textbook”, “Cypress Semiconductor Corporation Application Note AN2292” and the like.

It was found that, in a case in which the produced touch panel is used, it is possible to produce a touch panel which is excellent in terms of visibility due to the improvement of light transmittance, and is excellent in terms of responsiveness to the input of letters and the like or a screen operation using at least one of a bare hand, a hand in a glove and a stylus due to the improvement of conduction.

### INDUSTRIAL APPLICABILITY

Since the laminate for forming conductive films that is an embodiment of the invention is excellent in terms of patternability through development, transparency, conduction and durability (film strength) not only when used as it is but also when used as a transfer material, the laminate can be preferably used to produce, for example, pattern-shaped transparent conductive films, touch panels, display antistatic materials, electromagnetic wave shields, organic EL display electrodes, inorganic EL display electrodes, electronic paper, flexible display electrodes, flexible display antistatic films, display elements, and integrated solar cells.

All the contents of Japanese Patent Application Nos. 2011-102135, 2011-265207 and 2012-068270 disclosed herein are incorporated into the present specification for reference.

All the documents, patent applications and technical standards described in the specification are incorporated into the specification for reference to the same extent as cases in which it is specifically and respectively described that the respective documents, patent applications and technical standards are incorporated for reference.

What is claimed is:

1. A conductive member comprising:
a base material; and
a conductive layer provided on the base material, the conductive layer comprising
(i) a metallic nanowire having an average short-axis length of 150 nm or less, and
(ii) a binder,
the binder comprising a three-dimensional crosslinked structure that contains a partial structure represented by the following Formula (Ia) and a partial structure represented by the following Formula (IIa) or the following Formula (IIb) 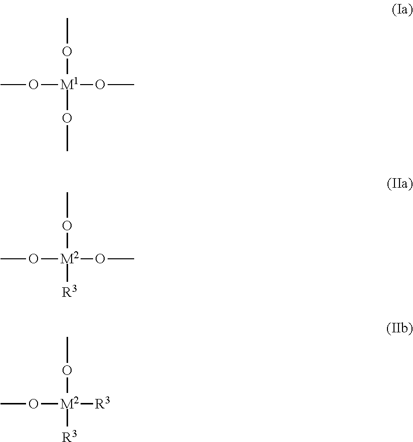
wherein, in the Formulae, each of M¹ and M² independently represents an element selected from the group consisting of Si, Ti, and Zr; and each R³ independently represents a hydrogen atom or a hydrocarbon group.

2. A conductive member comprising:
a base material; and
a conductive layer provided on the base material, the conductive layer comprising
(i) a metallic nanowire having an average short-axis length of 150 nm or less, and
(ii) a sol-gel cured product;
the sol-gel cured product being formed through hydrolysis and condensation of a tetraalkoxy compound represented by the following Formula (I) and an organoalkoxy compound represented by the following Formula (II):
M¹(OR¹)₄ Formula (I)
wherein, in Formula (I), M¹ represents an element selected from the group consisting of Si, Ti, and Zr; and R¹ represents a hydrocarbon group,
M²(OR²)ₐR³₄₋ₐ Formula (II)
wherein, in Formula (II), M² represents an element selected from the group consisting of Si, Ti, and Zr; each R² and each R³ independently represents a hydrogen atom or a hydrocarbon group; and “a” represents 2 or 3.

3. The conductive member according to claim 2, wherein a mass ratio of a content of the tetraalkoxy compound to a content of the organoalkoxy compound in the conductive layer is in a range of from 0.01/1 to 100/1.

4. The conductive member according to claim 2, wherein a mass ratio of a total content of the tetraalkoxy compound and the organoalkoxy compound to a content of the metallic nanowire in the conductive layer is in a range of from 0.5/1 to 25/1.

5. The conductive member according to claim 1, wherein both of M¹ and M² are Si.

6. The conductive member according to claim 1, wherein the metallic nanowire is a silver nanowire.

7. The conductive member according to claim 1, wherein a surface resistivity measured at a surface of the conductive layer is 1,000Ω/□ or less.

8. The conductive member according to claim 1, wherein an average film thickness of the conductive layer is in a range of from 0.005 μm to 0.5 μm.

9. The conductive member according to claim 1, wherein the conductive layer comprises a conductive region and a nonconductive region, and at least the conductive region comprises the metallic nanowire.

10. The conductive member according to claim 1, wherein the conductive member further comprises at least one intermediate layer between the base material and the conductive layer.

11. The conductive member according to claim 1, wherein the conductive member further comprises an intermediate layer between the base material and the conductive layer, the intermediate layer contacts the conductive layer, and the intermediate layer comprises a compound having a functional group that interacts with the metallic nanowire.

12. The conductive member according to claim 11, wherein the functional group is selected from the group consisting of an amido group, an amino group, a mercapto group, a carboxylic acid group, a sulfonic acid group, a phosphoric acid group, a phosphonic acid group and salts thereof.

13. The conductive member according to claim 1, wherein a ratio of a surface resistivity (Ω/□) of the conductive layer after an abrasion treatment to a surface resistivity (Ω/□) of the conductive layer before the abrasion treatment is 100 or less, the abrasion treatment being performed by reciprocating a gauze 50 times on the surface of the conductive layer under a load of 125 g/cm² using a continuous loading scratching intensity tester.

14. The conductive member according to claim 1, wherein a ratio of a surface resistivity (Ω/□) of the conductive layer after a bending test to a surface resistivity (Ω/□) of the conductive layer before the bending test is 2.0 or less, the bending test being performed by bending the conductive member 20 times using a cylindrical mandrel bending tester provided with a cylindrical mandrel having a diameter of 10 mm.

15. A production method of the conductive member according to claim 2 comprising:
(a) applying a liquid composition comprising the metallic nanowire, the tetraalkoxy compound and the organoalkoxy compound onto the base material to form a liquid film of the liquid composition on the base material; and
(b) hydrolyzing and condensing the tetraalkoxy compound and the organoalkoxy compound in the liquid film to form the sol-gel cured product.

16. The production method of the conductive member according to claim 15, further comprising forming at least one intermediate layer on a surface of the base material, at which the liquid film is to be formed, prior to the process (a).

17. The production method of the conductive member according to claim 15, further comprising (c) forming a patterned non-conductive region in the conductive layer after the process (b) such that the conductive layer has a conductive region and a non-conductive region.

18. The production method of the conductive member according to claim 15, wherein a mass ratio of a content of the tetraalkoxy compound to a content of the organoalkoxy compound in the conductive layer is in a range of from 0.01/1 to 100/1.

19. The production method of the conductive member according to claim 15, wherein a mass ratio of a total content of the tetraalkoxy compound and the organoalkoxy compound, to a content of the metallic nanowire in the conductive layer, is in a range of from 0.5/1 to 25/1.

20. A composition comprising:
(i) a metallic nanowire having an average short-axis length of 150 nm or less;
(ii) a tetraalkoxy compound represented by the following Formula (I) and an organoalkoxy compound represented by the following Formula (II); and
(iii) a liquid dispersion medium that disperses or dissolves the component (i) and the component (ii);
M¹(OR¹)₄ Formula (I)
wherein, in Formula (I), M¹ represents an element selected from the group consisting of Si, Ti, and Zr; and R¹ represents a hydrocarbon group,
M²(OR²)ₐR³₄₋ₐ Formula (II)
wherein, in Formula (II), M² represents an element selected from the group consisting of Si, Ti, and Zr; each R² and each R³ independently represent a hydrogen atom or a hydrocarbon group; and “a” represents 2 or 3.

21. A touch panel comprising the conductive member according to claim 1.

22. A solar cell comprising the conductive member according to claim 1.

23. The conductive member according to claim 2, wherein both of M¹ and M² are Si, and the metallic nanowire is a silver nanowire.

24. The conductive member according to claim 23, wherein a surface resistivity measured at a surface of the conductive layer is 1,0000Ω/□ or less, and an average film thickness of the conductive layer is in a range of from 0.005 μm to 0.5 μm.

25. The conductive member according to claim 24, wherein the conductive member further comprises an intermediate layer between the base material and the conductive layer, the intermediate layer contacts the conductive layer, the intermediate layer comprises a compound having a functional group that interacts with the metallic nanowire, and the functional group is selected from the group consisting of an amido group, an amino group, a mercapto group, a carboxylic acid group, a sulfonic acid group, a phosphoric acid group, a phosphonic acid group and salts thereof.

26. The conductive member according to claim 25, wherein a ratio of a surface resistivity (Ω/□) of the conductive layer after an abrasion treatment to a surface resistivity (Ω/□) of the conductive layer before the abrasion treatment is 100 or less, the abrasion treatment being performed by reciprocating a gauze 50 times on the surface of the conductive layer under a load of 125 g/cm² using a continuous loading scratching intensity tester, and a ratio of a surface resistivity (Ω/□) of the conductive layer after a bending test to a surface resistivity (Ω/□) of the conductive layer before the bending test is 2.0 or less, the bending test being performed by bending the conductive member 20 times using a cylindrical mandrel bending tester provided with a cylindrical mandrel having a diameter of 10 mm.

27. A touch panel comprising the conductive member according to claim 26.

28. A solar cell comprising the conductive member according to claim 26.
